(19) United States
(12) Patent Application Publication
(10) Pub. No.: US 2024/0072015 A1
(43) Pub. Date: Feb. 29, 2024

(54) DISPLAY PANEL, METHOD OF MANUFACTURING THE DISPLAY PANEL, AND ELECTRONIC APPARATUS INCLUDING THE DISPLAY PANEL

(71) Applicant: Samsung Display Co., LTD., Yongin-si (KR)

(72) Inventors: Jeongho Lee, Yongin-si (KR); Seunglyong Bok, Yongin-si (KR)

(21) Appl. No.: 18/234,296

(22) Filed: Aug. 15, 2023

(30) Foreign Application Priority Data
Aug. 26, 2022 (KR) 10-2022-0107798

(51) Int. Cl. H01L 25/075; H01L 25/16; H01L 33/62

(52) U.S. Cl. CPC H01L 25/0753; H01L 25/167; H01L 33/62; H01L 2933/0066

(57) ABSTRACT

A display panel includes a substrate including first and second areas spaced apart from each other, and a first display area surrounding the first area and the second area, a plurality of first light-emitting diodes in the first display area and respectively electrically connected to a plurality of first sub-pixel circuits, a plurality of second light-emitting diodes in the first area, a plurality of second sub-pixel circuits respectively electrically connected to the plurality of second light-emitting diodes, and a groove surrounding the second area and having an undercut shape, wherein the substrate includes a first base layer, a first barrier layer, a second base layer, and a second barrier layer, and further includes a concave portion in a region between two adjacent second light-emitting and recessed into the second barrier layer and the second base layer, and a hole in the second area and penetrating through the substrate.

### CROSS-REFERENCE TO RELATED APPLICATION

The present application claims priority to and the benefit of Korean Patent Application No. 10-2022-0107798, filed on Aug. 26, 2022, in the Korean Intellectual Property Office, the entire disclosure of which is incorporated herein by reference.

### BACKGROUND

### 1. Field

Aspects of one or more embodiments relate to a display panel including a plurality of transmission areas, a method of manufacturing the display panel, and an electronic apparatus including the display panel.

### 2. Description of the Related Art

Recently, display panels have been diversified in their uses. In addition, as display panels are becoming relatively thinner and lighter, the range of uses of the display panels has widened.

The variety of functions for connecting or linking to a display panel has increased with the enlargement of an area occupied by a display area of the display panel. As a method of adding various functions to a display panel and an electronic apparatus including the display panel while enlarging an area occupied by a display area of the display panel, various types of display panels have been studied.

The above information disclosed in this Background section is only for enhancement of understanding of the background and therefore the information discussed in this Background section does not necessarily constitute prior art.

### SUMMARY

Aspects of one or more embodiments relate to a display panel including a plurality of transmission areas, a method of manufacturing the display panel, and an electronic apparatus including the display panel.

One or more embodiments include a display panel having a structure in which various types of components may be arranged in a plurality of transmission areas in a display area, a method of manufacturing the display panel, and an electronic apparatus including the display panel. However, these problems are merely illustrations, and the scope of embodiments according to the present disclosure is not limited thereto.

Additional aspects will be set forth in part in the description which follows and, in part, will be apparent from the description, or may be learned by practice of the presented embodiments of the disclosure.

According to one or more embodiments, a display panel includes a substrate including a first area, a second area spaced apart from the first area, and a first display area surrounding the first area and the second area, a plurality of first sub-pixel circuits in the first display area, a plurality of first light-emitting diodes arranged in the first display area and respectively electrically connected to the plurality of first sub-pixel circuits, a plurality of second light-emitting diodes in the first area, a plurality of second sub-pixel circuits respectively electrically connected to the plurality of second light-emitting diodes, and a groove surrounding the second area and having an undercut shape, wherein the substrate includes a first base layer, a first barrier layer on the first base layer, a second base layer on the first barrier layer, and the second barrier layer on the second base layer, wherein the substrate further includes a concave portion corresponding to a region between two adjacent second light-emitting diodes in the first area and having a shape recessed into the second barrier layer and the second base layer, and a hole corresponding to the second area and penetrating through the second barrier layer, the second base layer, the first barrier layer, and the first base layer.

According to some embodiments, a first vertical distance from an upper surface of the first base layer to a bottom surface of the groove may be equal to or greater than a second vertical distance from the upper surface of the first base layer to a bottom surface of the concave portion.

According to some embodiments, the first area may include a transmission area corresponding to the concave portion of the substrate.

According to some embodiments, one of two second sub-pixel circuits selected from among the plurality of second sub-pixel circuits may be in a first peripheral area on a first side of the first area, and an other one of the two second-pixel circuits may be in a second peripheral area on a second side of the first area, the second side being opposite to the first side.

According to some embodiments, the one of the two second sub-pixel circuits may be arranged on a side opposite to the second area with the first area therebetween, and the other one of the two second sub-pixel circuits may be between the first area and the second area.

According to some embodiments, the display panel may further include a first conductive bus line electrically connecting the one of the two second sub-pixel circuits and a corresponding second light-emitting diode from among the plurality of second light-emitting diodes to each other and extending in a first direction, and a second conductive bus line electrically connecting the other one of the two second sub-pixel circuits and a corresponding second light-emitting diode from among the plurality of second light-emitting diodes to each other and extending in the first direction.

According to some embodiments, each of the first conductive bus line and the second conductive bus line may include a transmissive conductive material.

According to some embodiments, a portion of any one of the first conductive bus line and the second conductive bus line may overlap the concave portion.

According to some embodiments, a first height from the substrate to a first electrode of any one of the plurality of second light-emitting diodes in the first area may be less than a second height from the substrate to a first electrode of any one of the plurality of first light-emitting diodes in the first display area.

According to some embodiments, the display panel may further include an organic insulating layer between the substrate and a first electrode of any one of the plurality of second light-emitting diodes in the first area, wherein the organic insulating layer may overlap the concave portion of the substrate.

According to some embodiments, the substrate may further include another concave portion arranged in the first area and spaced apart from the concave portion.

According to one or more embodiments, a method of manufacturing a display panel including a first display area in which a plurality of first light-emitting diodes is arranged, a first area in which a plurality of second light-emitting diodes is arranged, and a second area spaced apart from the first area includes preparing a substrate including a first base layer, a first barrier layer on the first base layer, a second base layer on the first barrier layer, and a second barrier layer on the second base layer, wherein the plurality of first light-emitting diodes and the plurality of second light-emitting diodes are arranged on the substrate, forming a groove corresponding to a peripheral area of the second area, surrounding the second area, and having an undercut shape, and forming a concave portion corresponding to a region between two adjacent second light-emitting diodes in the first area and having a shape recessed into the second barrier layer and the second base layer, wherein, in the forming of the groove and the forming of the concave portion, a mask made of a same material is used.

According to some embodiments, the mask may include indium gallium zinc oxide (IGZO).

According to some embodiments, a first vertical distance from an upper surface of the first base layer to a bottom surface of the groove may be equal to or greater than a second vertical distance from the upper surface of the first base layer to a bottom surface of the concave portion.

According to some embodiments, the forming of the concave portion may include forming a hole penetrating through the second barrier layer, and forming an opening overlapping the hole of the second barrier layer in the second base layer.

According to some embodiments, the method may further include forming an organic insulating layer between the substrate and the mask, and forming a metal pattern layer on the organic insulating layer, wherein the forming of the groove may include removing a portion of the organic insulating layer by using the mask, and the metal pattern layer may include a tip protruding toward the groove from a point where an inner side surface of the organic insulating layer, from which a portion thereof is removed, and a bottom surface of the metal pattern layer meet each other.

According to some embodiments, the method may further include forming a lower layer below the organic insulating layer.

According to some embodiments, the forming of the groove may include forming a hole penetrating through the second barrier layer below the mask, and forming an opening overlapping the hole of the second barrier layer in the second base layer.

According to one or more embodiments, an electronic apparatus includes a display panel including a first area, a second area spaced apart from the first area, and a first display area surrounding the first area and the second area, a first component corresponding to the first area of the display panel and on a rear surface of the display panel, and a second component corresponding to the second area of the display panel and on the rear surface of the display panel.

According to some embodiments, the display panel of the electronic apparatus may include a substrate, a plurality of first sub-pixel circuits on the substrate and positioned in the first display area, a plurality of first light-emitting diodes arranged in the first display area and respectively electrically connected to the plurality of first sub-pixel circuits, a plurality of second light-emitting diodes in the first area, a plurality of second sub-pixel circuits respectively electrically connected to the plurality of second light-emitting diodes, and a groove surrounding the second area and having an undercut shape, the substrate may include a first base layer, a first barrier layer on the first base layer, a second base layer on the first barrier layer, and a second barrier layer on the second base layer, and the substrate may further include a concave portion corresponding to a region between two adjacent second light-emitting diodes in the first area and having a shape recessed into the second barrier layer and the second base layer, and a hole corresponding to the second area and penetrating through the second barrier layer, the second base layer, the first barrier layer, and the first base layer.

According to some embodiments, a first vertical distance from an upper surface of the first base layer to a bottom surface of the groove may be equal to or greater than a second vertical distance from the upper surface of the first base layer to a bottom surface of the concave portion.

According to some embodiments, the first area may include a transmission area corresponding to the concave portion of the substrate.

According to some embodiments, one of two second sub-pixel circuits selected from among the plurality of second sub-pixel circuits may be in a first peripheral area on a first side of the first area, and another one of the two second sub-pixel circuits may be in a second peripheral area on a second side of the first area, the second side being opposite to the first side.

According to some embodiments, the display panel may further include a first conductive bus line electrically connecting the one of the two second sub-pixel circuits and a corresponding second light-emitting diode from among the plurality of second light-emitting diodes to each other and extending in a first direction, and a second conductive bus line electrically connecting the other one of the two second sub-pixel circuits and a corresponding second light-emitting diode from among the plurality of second light-emitting diodes to each other and extending in the first direction.

According to some embodiments, each of the first conductive bus line and the second conductive bus line may include a transmissive conductive material.

According to some embodiments, a portion of any one of the first conductive bus line and the second conductive bus line may overlap the concave portion.

According to some embodiments, a first height from the substrate to a first electrode of any one of the plurality of second light-emitting diodes in the first area may be less than a second height from the substrate to a first electrode of any one of the plurality of first light-emitting diodes in the first display area.

According to some embodiments, the display panel may further include an organic insulating layer between the substrate and a first electrode of any one of the plurality of second light-emitting diodes in the first area, and the organic insulating layer may overlap the concave portion of the substrate.

According to some embodiments, the substrate may further include another concave portion arranged in the first area and spaced apart from the concave portion.

According to some embodiments, each of the first component and the second component may include an electronic element using light, and the electronic element of the first component may be different from the electronic element of the second component.

According to some embodiments, the electronic element of each of the first component and the second component may include a sensor or a camera.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a perspective view schematically illustrating an electronic apparatus according to some embodiments;

FIG. 2 is a cross-sectional view taken along a line II-II′ of FIG. 1, schematically illustrating the electronic apparatus according to some embodiments;

FIG. 3 is a schematic plan view of a display panel according to some embodiments;

FIGS. 4A, 4B, and 4C are plan views, each schematically illustrating a portion of a display panel according to some embodiments;

FIG. 5 is an equivalent circuit diagram schematically illustrating a light-emitting diode and a sub-pixel circuit in a display panel according to some embodiments;

FIG. 6A is a plan view of a portion of a display panel according to some embodiments;

FIG. 6B is a plan view of a portion of a display panel according to some embodiments;

FIG. 7 is a cross-sectional view schematically illustrating a structure of a first display area of a display panel according to some embodiments;

FIG. 8 is a cross-sectional view taken along a line VIII-VIII′ of FIG. 6A, illustrating the display panel according to some embodiments;

FIG. 9 is a cross-sectional view of a display panel according to some embodiments, illustrating cross-sections of a first area and a first peripheral area;

FIG. 10 is a cross-sectional view taken along a line X-X′ of FIG. 6A, illustrating the display panel according to some embodiments;

FIGS. 11A and 11B are cross-sectional views, each illustrating a first area of a display panel according to some embodiments;

FIG. 12 is a plan view viewed from a direction perpendicular to a substrate of FIGS. 11A and 11B, schematically illustrating the first area of the display panel according to some embodiments;

FIG. 13 is a cross-sectional view of a display panel according to some embodiments, illustrating a second area and a second peripheral area;

FIGS. 14A to 14E are cross-sectional views illustrating an operation of forming a concave portion and a groove of a display panel according to some embodiments;

FIGS. 15A to 15E are cross-sectional views illustrating an operation of forming a concave portion and a groove of a display panel according to some embodiments.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the example embodiments set forth herein.

Aspects of some embodiments of the present disclosure will now be described more fully with reference to the accompanying drawings, in which embodiments of the disclosure are shown. Like reference numerals in the drawings denote like elements, and thus their description will be omitted.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the present disclosure, and are not intended to preclude the possibility that one or more other features or elements may exist or may be added.

It will be understood that when a layer, region, or component is referred to as being formed on another layer, region, or component, it can be directly or indirectly formed on the other layer, region, or component. That is, for example, intervening layers, regions, or components may be present.

Sizes of components in the drawings may be exaggerated for convenience of explanation. In other words, because sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the disclosure, “A and/or B” may include “A,” “B,” or “A and B.”

It will be understood that when a layer, region, or component is referred to as being connected to another layer, region, or component, it can be directly or indirectly connected to the other layer, region, or component. That is, for example, intervening layers, regions, or components may be present. For example, it will be understood that when a layer, region, or component is referred to as being electrically connected to another layer, region, or component, it can be directly or indirectly electrically connected to the other layer, region, or component. That is, for example, intervening layers, regions, or components may be present.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

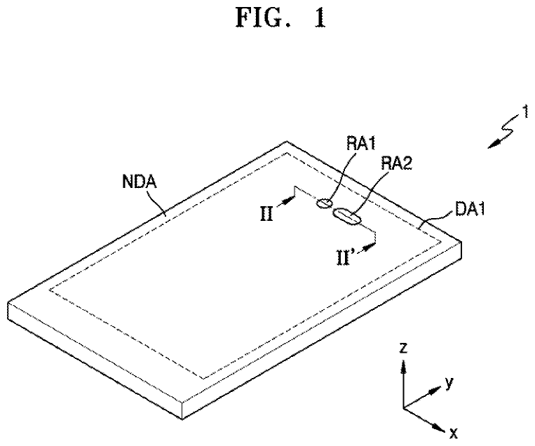

FIG. 1 is a perspective view schematically illustrating an electronic apparatus 1 according to some embodiments.

Referring to FIG. 1, the electronic apparatus 1 includes a first area RA1, a second area RA2, and a first display area DA1 surrounding the first area RA1 and the second area RA2. For example, the first area RA1 and the second area RA2 may be inside the first display area DA1, and the first display area DA1 may entirely surround the first area RA1 and the second area RA2. The first display area DA1 may display images by using light emitted from a plurality of sub-pixels arranged in the first display area DA1.

The electronic apparatus 1 may include a non-display area NDA outside (e.g., in a periphery or outside a footprint of) the first display area DA1. The non-display area NDA may be outside the first display area DA1 and may not display images, and may entirely surround the first display area DA1. A driver or the like for providing electrical signals or power to the first display area DA1 may be arranged in the non-display area NDA. A pad, which is an area to which an electronic device or a printed circuit board may be electrically connected, may be arranged in the non-display area NDA.

Hereinafter, for convenience of description, a case where the electronic apparatus 1 is a smartphone is described, but the electronic apparatus 1 according to embodiments of the present disclosure is not limited thereto. For example, the electronic apparatus 1 may be a portable electronic device, such as a mobile phone, a smartphone, a tablet personal computer (PC), a mobile communication terminal, an electronic notebook, an electronic book, a portable multimedia player (PMP), a navigation device, an Ultra Mobile PC (UMPC), or the like, and may also be applied to various products, such as a television, a laptop computer, a monitor, an advertisement board, an Internet of things (loT) device, or the like. In addition, the electronic apparatus 1 according to some embodiments may be applied to a wearable device, such as a smart watch, a watch phone, a glasses-type display, and a head mounted display (HMD). Also, the electronic apparatus 1 according to some embodiments may be applied to a dashboard of a vehicle, a center fascia of a vehicle or a center information display (CID) located on a dashboard, a rear-view mirror display replacing a side mirror of a vehicle, and a display screen located on a back surface of a front seat as entertainment for a passenger in a back seat of a vehicle.

Each of the first area RA1 and the second area RA2 may each have a smaller area than the area of the first display area DA1. According to some embodiments, FIG. 1 illustrates that the first area RA1 and the second area RA2 have different shapes from each other, where the first area RA1 has a circular shape and the second area RA2 has an approximately elliptical shape with both sides rounded, but the disclosure is not limited thereto. According to some embodiments, the first area RA1 and the second area RA2 may both have the same shape (e.g., a circular shape, a polygonal shape, or the like).

FIG. 1 illustrates that the first area RA1 and the second area RA2 are arranged at the center of an upper side (+y direction) of the first display area DA1 having an approximately rectangular shape when viewed from a direction (e.g., a z direction) approximately perpendicular to an upper surface of the electronic apparatus 1, but the disclosure is not limited thereto. The first area RA1 and the second area RA2 may be arranged, for example, on an upper right side or an upper left side of the first display area DA1.

The first area RA1 and the second area RA2 may each include a transmission area through which light or sound may pass. The transmittance of any one of the first area RA1 and the second area RA2 may be different from the transmittance of the other one. Any one of the first area RA1 and the second area RA2 may implement an image through a sub-pixel circuit arranged in that one area.

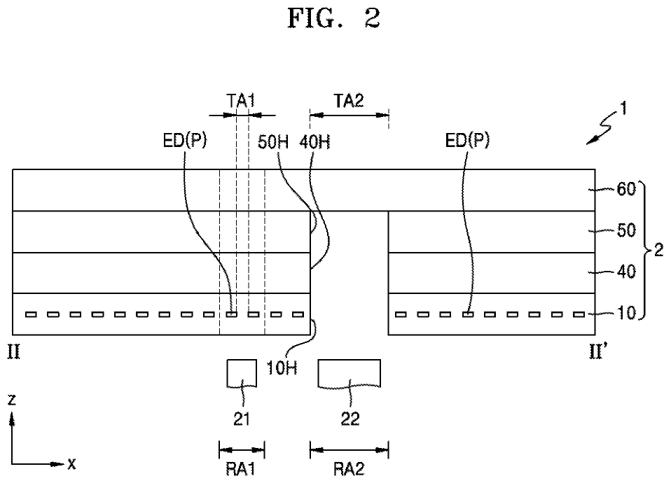

FIG. 2 is a cross-sectional view taken along a line II-II′ of FIG. 1, schematically illustrating the electronic apparatus 1 according to some embodiments.

Referring to FIG. 2, the electronic apparatus 1 may include a display panel 2 including a display layer 10, an input sensing layer 40 located on an upper surface of the display layer 10, an optical functional layer 50 located on the input sensing layer 40, and a cover window 60. The electronic apparatus 1 may include a first component 21 and a second component 22, which are located on a rear surface (bottom surface) of the display panel 2.

The display layer 10 may display images by using light-emitting diodes ED. The light-emitting diodes ED may each include an organic light-emitting diode including an organic material as an emission layer thereof. Alternatively, the light-emitting diodes ED may include inorganic light-emitting diodes, quantum dot light-emitting diodes, or the like.

The input sensing layer 40 may obtain coordinate information according to an external input, for example, a touch event. The input sensing layer 40 may include a sensing electrode (or a touch electrode) and a trace line connected to the sensing electrode. The input sensing layer 40 may be located on the display layer 10. The input sensing layer 40 may sense an external input through a mutual-cap method and/or a self-cap method.

The input sensing layer 40 may be directly formed on the display layer 10, or may be formed separately and then bonded to the display layer 10 through an adhesive layer, such as an optical clear adhesive (OCA). For example, the input sensing layer 40 may be continuously formed after an operation of forming the display layer 10, and in this case, the adhesive layer may not be between the input sensing layer 40 and the display layer 10.

The optical functional layer 50 may include an anti-reflection layer. The anti-reflection layer may reduce the reflectance of light (external light) incident from the outside toward the display layer 10 through the cover window 60. The anti-reflection layer may include a retarder and a polarizer.

According to some embodiments, the anti-reflection layer may include a black matrix and color filters. The color filters may be arranged by considering a color of light emitted from each of sub-pixels (e.g., light-emitting diodes ED) of the display layer 10. According to some embodiments, the anti-reflection layer may include a destructive interference structure. The destructive interference structure may include a first reflective layer and a second reflective layer, which are on different layers. First reflected light and second reflected light respectively reflected by the first reflective layer and the second reflective layer may destructively interfere with each other, and accordingly, the reflectance of external light may be reduced.

The optical functional layer 50 may include a lens layer. The lens layer may improve light emission efficiency of light emitted from the display layer 10 or reduce color deviation. The lens layer may include a layer having a concave or convex lens shape, and/or may include a plurality of layers having different refractive indices. The optical functional layer 50 may include all of the anti-reflection layer and the lens layer described above, or may include any one of the anti-reflection layer and the lens layer.

The cover window 60 may protect the front surface (upper surface) of the display panel 2 and/or the electronic apparatus 1. The cover window 60 may include a resin, such as polyimide. Alternatively, the cover window 60 may include a glass substrate, such as ultra-thin glass (UTG).

The first area RA1 and the second area RA2 may each include a transmission area. According to some embodiments, the first area RA1 may include a first transmission area TA1 between neighboring sub-pixels, for example, between neighboring light-emitting diodes ED, and the second area RA2 may include a second transmission area TA2 having the same area and shape (e.g., a planar shape) as the second area RA2.

The first component 21 may be arranged in the first area RA1, and the second component 22 may be arranged in the second area RA2. The first component 21 and the second component 22 may each be an electronic element using light or sound. Light or sound emitted from the first component 21 and the second component 22 and/or travelling to the first component 21 and the second component 22 may pass through the first transmission area TA1 and the second transmission area TA2, respectively.

When light passes through the first transmission area TA1 and the second transmission area TA2, the light transmittance of each of the first transmission area TA1 and the second transmission area TA2 may be 30% or more, 40% or more, 50% or more, 85% or more, or 90% or more.

The first component 21 and the second component 22 may each include a sensor that measures distance, such as a proximity sensor, a sensor that recognizes a part of a user's body (e.g., fingerprint, iris, face, or the like), a small lamp that outputs light, or an image sensor (e.g., a camera) that captures an image. An electronic element using light may use light of various wavelengths, such as visible light, infrared light, or the like. An electronic element using sound may use ultrasonic waves or sound of another frequency band.

FIG. 2 illustrates that one first component 21 is arranged in the first area RA1, and one second component 22 is arranged in the second area RA2, but embodiments according to the present disclosure are not limited thereto. A plurality of components may be arranged in the first area RA1, and/or a plurality of components may be arranged in the second area RA2.

The display layer 10, the input sensing layer 40 and/or the optical functional layer 50 may include a hole corresponding to any one of the first and second areas RA1 and RA2. According to some embodiments, FIG. 2 illustrates that the display layer 10, the input sensing layer 40, and the optical functional layer 50 include holes 10H, 40H, and 50H, respectively, in the second area RA2. Accordingly, the transmittance of the second area RA2 may be greater than the transmittance of the first area RA1. In some embodiments, the second component 22 in the second area RA2 may include an electronic element having a greater amount of light received or emitted than that of the first component 21 in the first area RA1.

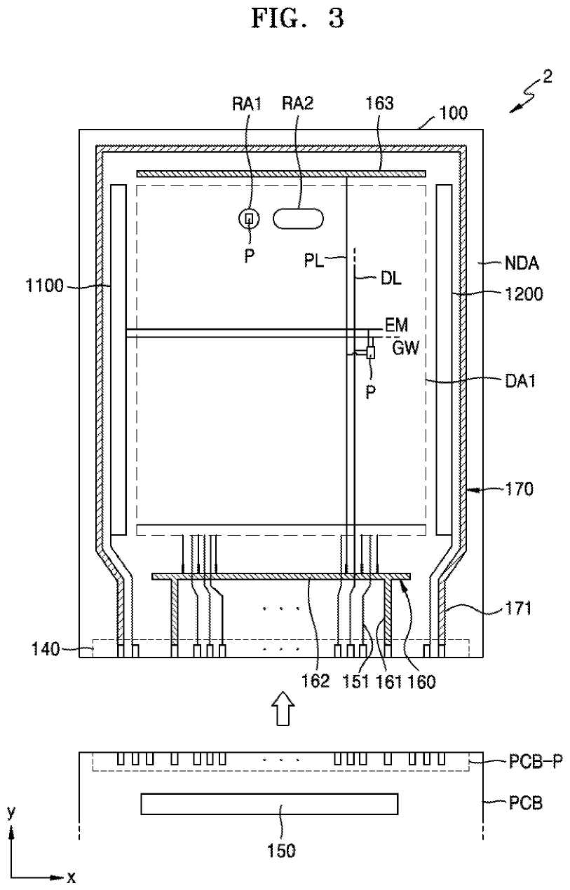

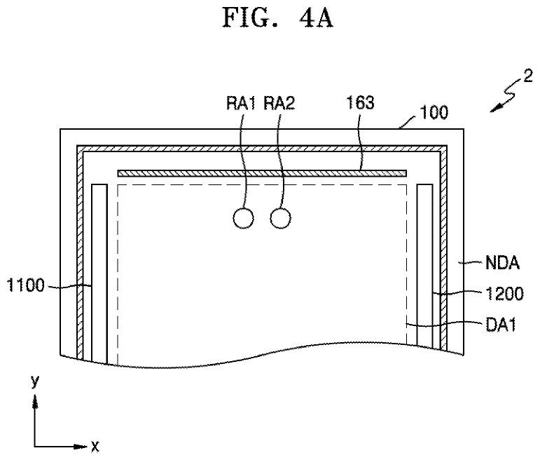

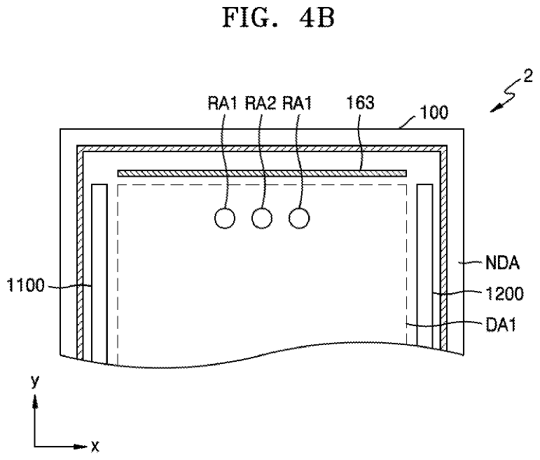

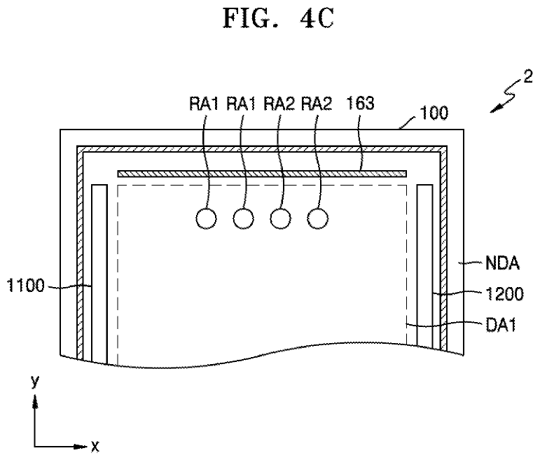

FIG. 3 is a schematic plan view of a display panel 2 according to some embodiments, and FIGS. 4A, 4B, and 4C are plan views each schematically illustrating a portion of a display panel 2 according to some embodiments.

Referring to FIG. 3, the display panel 2 may include the first area RA1, the second area RA2, the first display area DA1, and the non-display area NDA. FIG. 3 may be a view of a substrate 100 of the display panel 2. For example, the display panel 2 including the first area RA1, the second area RA2, the first display area DA1, and the non-display area NDA may show that the substrate 100 includes the first area RA1, the second area RA2, the first display area DA1, and the non-display area NDA.

The display panel 2 may include a plurality of sub-pixels P in the first display area DA1 and the first area RA1. Each of the plurality of sub-pixels P may include a light-emitting diode. The light-emitting diode of each sub-pixel P may emit, for example, red, green, blue, or white light.

In the non-display area NDA, a first outer driving circuit 1100, a second outer driving circuit 1200, a terminal 140, a data driving circuit 150, a first power supply line 160, and a second power supply line 170 may be arranged.

The first outer driving circuit 1100 may include a scan and control driving circuit. The first outer driving circuit 1100 may provide a scan signal and an emission control signal to each sub-pixel P respectively through a scan line GW and an emission control line EM. The second outer driving circuit 1200 may include a scan and control driving circuit. The second outer driving circuit 1200 may be arranged in parallel with the first outer driving circuit 1100 with the first display area DA1 therebetween. Similarly to the first outer driving circuit 1100, the second outer driving circuit 1200 may provide a scan signal and an emission control signal to a corresponding sub-pixel P respectively through the scan line GW and the emission control line EM.

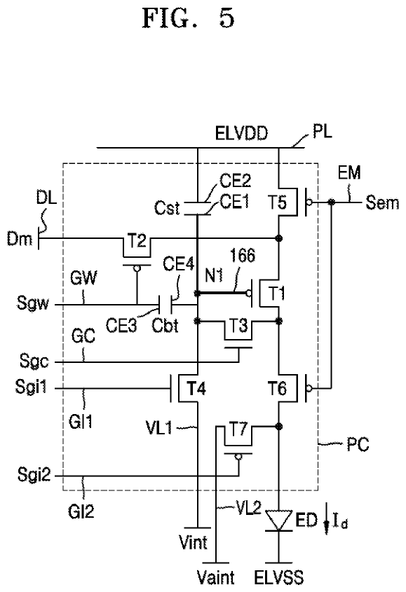

The terminal 140 may be arranged on one side of the non-display area NDA. The terminal 140 may not be covered by an insulating layer, but exposed to be electrically connected to a printed circuit board PCB. A terminal PCB-P of the printed circuit board PCB may be electrically connected to the terminal 140 of the display panel 2. The printed circuit board PCB may deliver a signal or power of a controller to the display panel 2. A control signal generated by the controller may be transmitted to each of the first and second outer driving circuits 1100 and 1200 via the printed circuit board PCB. The controller may provide a driving voltage ELVDD (refer to FIG. 5) and a common voltage ELVSS (refer to FIG. 5) to the first and second power supply lines 160 and 170 via first and second connection lines 161 and 171, respectively. The driving voltage ELVDD of the first power supply line 160 may be provided to a driving voltage line PL, and the common voltage ELVSS of the second power supply line 170 may be provided to an electrode (e.g., a cathode) of a light-emitting diode of each sub-pixel P.

The data driving circuit 150 is electrically connected to a data line DL. A data signal of the data driving circuit 150 may be provided to a corresponding sub-pixel P through a connection line 151 connected to the terminal 140 and the data line DL connected to the connection line 151. FIG. 3 illustrates that the data driving circuit 150 is arranged in the printed circuit board PCB, but according to some embodiments, the data driving circuit 150 may be arranged in the substrate 100. For example, the data driving circuit 150 may be arranged between the terminal 140 and the first power supply line 160.

The first power supply line 160 may include a first subline 162 and a second subline 163, which extend parallel to each other in an x direction with the first display area DA1 therebetween. The second power supply line 170 may partially surround the first display area DA1 in a loop shape of which one side is open.

FIG. 3 illustrates that the first area RA1 and the second area RA2 have different areas and/or shapes from each other, but embodiments according to the present disclosure are not limited thereto. According to some embodiments, as shown in FIG. 4A, each of the first area RA1 and the second area RA2 may have a circular shape. In some embodiments, a plurality of first areas RA1 and/or a plurality of second areas RA2 may be arranged inside the first display area DA1. For example, as shown in FIG. 4B, two first areas RA1 may be arranged, and one second area RA2 may be arranged between the two first areas RA1. According to some embodiments, one first area RA1 may be arranged between two second areas RA2. According to some embodiments, as shown in FIG. 4C, two first areas RA1 and two second areas RA2 may be arranged. The two first areas RA1 may be arranged adjacent to each other, and the two second areas RA2 may be arranged adjacent to each other. Alternatively, the first areas RA1 and the second areas RA2 may be arranged in various ways, such as being alternately arranged. The number of each of the first areas RA1 and the second areas RA2 may be variously changed, such as three or more.

FIG. 5 is an equivalent circuit diagram schematically illustrating a light-emitting diode ED and a sub-pixel circuit PC in a display panel according to some embodiments.

Referring to FIG. 5, the light-emitting diode ED may be electrically connected to the sub-pixel circuit PC. The sub-pixel circuit PC may include first to seventh transistors T1, T2, T3, T4, T5, T6, and T7, a storage capacitor Cst, and a boost capacitor Cbt. According to some embodiments, the sub-pixel circuit PC may not include the boost capacitor Cbt.

Some of the first to seventh transistors T1, T2, T3, T4, T5, T6, and T7 may be n-channel metal-oxide-semiconductor field-effect transistors (MOSFET) (NMOS), and the remaining may be p-channel MOSFETs (PMOS). According to some embodiments, as shown in FIG. 5, the third and fourth transistors T3 and T4 may be NMOSs, and the remaining transistors may be PMOSs. For example, the third and fourth transistors T3 and T4 may be NMOSs, each including an oxide-based semiconductor material, and the remaining transistors may be PMOSs, each including a silicon-based semiconductor material. According to some embodiments, the third, fourth, and seventh transistors T3, T4, and T7 may be NMOSs, and the remaining transistors may be PMOSs.

The first to seventh transistors T1, T2, T3, T4, T5, T6, and T7, the storage capacitor Cst, and the boost capacitor Cbt may be connected to a signal line. The signal line may include the scan line GW, the emission control line EM, a compensation gate line GC, a first initialization gate line GI1, a second initialization gate line GI2, and a data line DL. The sub-pixel circuit PC may be electrically connected to a voltage line, for example, the driving voltage line PL, a first initialization voltage line VL1, and a second initialization voltage line VL2.

The first transistor T1 may be a driving transistor. A first gate electrode of the first transistor T1 may be connected to the storage capacitor Cst, a first electrode of the first transistor T1 may be electrically connected to the driving voltage line PL via the fifth transistor T5, and a second electrode of the first transistor T1 may be electrically connected to a first electrode (e.g., an anode) of the light-emitting diode ED via the sixth transistor T6. One of the first electrode and the second electrode of the first transistor T1 may be a source electrode, and the other one may be a drain electrode. The first transistor T1 may supply a driving current Id to the light-emitting diode ED according to a switching operation of the second transistor T2.

The second transistor T2 may be a switching transistor. A second gate electrode of the second transistor T2 may be connected to the scan line GW, a first electrode of the second transistor T2 may be connected to the data line DL, and a second electrode of the second transistor T2 may be electrically connected to the driving voltage line PL via the fifth transistor T5 while being connected to the first electrode of the first transistor T1. One of the first electrode and the second electrode of the second transistor T2 may be a source electrode, and the other one may be a drain electrode. The second transistor T2 may be turned on according to a scan signal Sgw received through the scan line GW, and may perform a switching operation of delivering a data signal Dm delivered to the data line DL to the first electrode of the first transistor T1.

The third transistor T3 may be a compensation transistor that compensates for a threshold voltage of the first transistor T1. A third gate electrode of the third transistor T3 is connected to the compensation gate line GC. A first electrode of the third transistor T3 is connected to a lower electrode CE1 of the storage capacitor Cst and the first gate electrode of the first transistor T1 through a node connection line 166. The first electrode of the third transistor T3 may be connected to the fourth transistor T4. A second electrode of the third transistor T3 is electrically connected to the first electrode (e.g., an anode) of the light-emitting diode ED via the sixth transistor T6 while being connected to the second electrode of the first transistor T1. One of the first electrode and the second electrode of the third transistor T3 may be a source electrode, and the other one may be a drain electrode.

The third transistor T3 is turned on according to a compensation signal Sgc received through the compensation gate line GC to electrically connect the first gate electrode and the second electrode (e.g., a drain electrode) of the first transistor T1 to each other to diode-connect the first transistor T1.

The fourth transistor T4 may be a first initialization transistor that initializes the first gate electrode of the first transistor T1. A fourth gate electrode of the fourth transistor T4 is connected to the first initialization gate line GI1. A first electrode of the fourth transistor T4 is connected to the first initialization voltage line VL1. A second electrode of the fourth transistor T4 may be connected to a lower electrode CE1 of the storage capacitor Cst, the first electrode of the third transistor T3, and the first gate electrode of the first transistor T1. One of the first electrode and the second electrode of the fourth transistor T4 may be a source electrode, and the other one may be a drain electrode. The fourth transistor T4 may be turned on according to a first initialization signal Sgi1 received through the first initialization gate line GI1 to be configured to transmit a first initialization voltage Vint to the first gate electrode of the first transistor T1 to perform an initialization operation of initializing a voltage of the first gate electrode of the first transistor T1.

The fifth transistor T5 may be an operation control transistor. A fifth gate electrode of the fifth transistor T5 is connected to the emission control line EM, a first electrode of the fifth transistor T5 is connected to the driving voltage line PL, and a second electrode of the fifth transistor T5 is connected to the first electrode of the first transistor T1 and the second electrode of the second transistor T2. One of the first electrode and the second electrode of the fifth transistor T5 may be a source electrode, and the other one may be a drain electrode.

The sixth transistor T6 may be an emission control transistor. A sixth gate electrode of the sixth transistor T6 is connected to the emission control line EM, a first electrode of the sixth transistor T6 is connected to the second electrode of the first transistor T1 and the second electrode of the third transistor T3, and a second electrode of the sixth transistor T6 is electrically connected to a second electrode of the seventh transistor T7 and the first electrode (e.g., an anode) of the light-emitting diode ED. One of the first electrode and the second electrode of the sixth transistor T6 may be a source electrode, and the other one may be a drain electrode.

The fifth transistor T5 and the sixth transistor T6 are simultaneously (or concurrently) turned on according to an emission control signal Sem received through the emission control line EM to allow the driving voltage ELVDD to be transmitted to the light-emitting diode ED, and the driving current Id may flow through the light-emitting diode ED.

The seventh transistor T7 may be a second initialization transistor that initializes the first electrode (e.g., an anode) of the light-emitting diode ED. A seventh gate electrode of the seventh transistor T7 is connected to the second initialization gate line GI2. A first electrode of the seventh transistor T7 is connected to the second initialization voltage line VL2. A second electrode of the seventh transistor T7 is connected to the second electrode of the sixth transistor T6 and the first electrode (e.g., an anode) of the light-emitting diode ED. The seventh transistor T7 is turned on according to a second initialization signal Sgi2 received through the second initialization gate line GI2, and may be configured to transmit a second initialization voltage Vaint to the first electrode (e.g., an anode) of the light-emitting diode ED to initialize the first electrode of the light-emitting diode ED.

According to some embodiments, the second initialization gate line GI2 may be a subsequent scan line. For example, a second initialization gate line GI2 connected to a seventh transistor T7 of a sub-pixel circuit PC arranged in the i-th row (wherein i is a natural number) may correspond to a scan line of a sub-pixel circuit PC arranged in the (i+1)-th row. According to some embodiments, the second initialization gate line GI2 may be the emission control line EM. For example, the emission control line EM may be electrically connected to the fifth to seventh transistors T5, T6, and T7.

The storage capacitor Cst includes the lower electrode CE1 and an upper electrode CE2. The lower electrode CE1 of the storage capacitor Cst is connected to the first gate electrode of the first transistor T1, and the upper electrode CE2 of the storage capacitor Cst is connected to the driving voltage line PL. The storage capacitor Cst may store a charge corresponding to a difference between a voltage of the first gate electrode of the first transistor T1 and the driving voltage ELVDD.

The boost capacitor Cbt includes a third electrode CE3 and a fourth electrode CE4. The third electrode CE3 may be connected to the second gate electrode of the second transistor T2 and the scan line GW, and the fourth electrode CE4 may be connected to the first electrode of the third transistor T3 and the node connection line 166. When the scan signal Sgw supplied to the scan line GW is turned off, the boost capacitor Cbt may increase the voltage of a first node N1, and when the voltage of the first node N1 is increased, a black gradation may be clearly expressed.

The first node N1 may be an area to which the first gate electrode of the first transistor T1, the first electrode of the third transistor T3, the second electrode of the fourth transistor T4, and the fourth electrode CE4 of the boost capacitor Cbt are connected.

According to some embodiments, it is described in FIG. 5 that the third and fourth transistors T3 and T4 are NMOSs, and the first, second, and fifth to seventh transistors T1, T2, T5, T6, and T7 are PMOSs. The first transistor T1, which directly affects the brightness of a display apparatus, may be configured to include a semiconductor layer including polycrystalline silicon having high reliability, thereby implementing a display panel having high resolution.

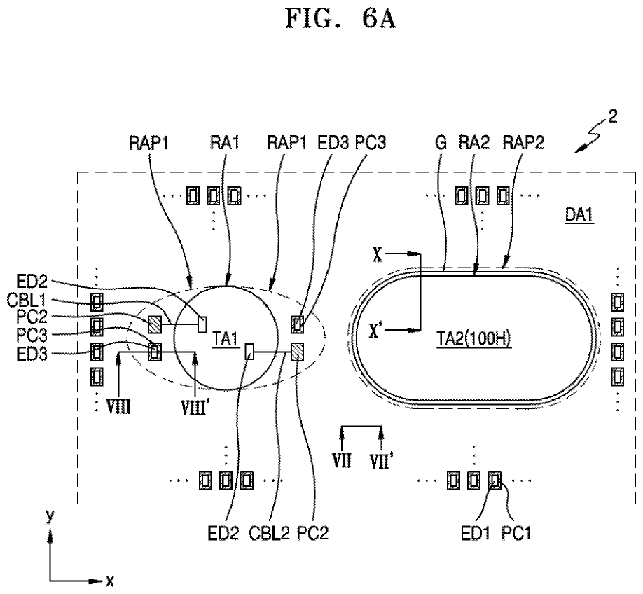

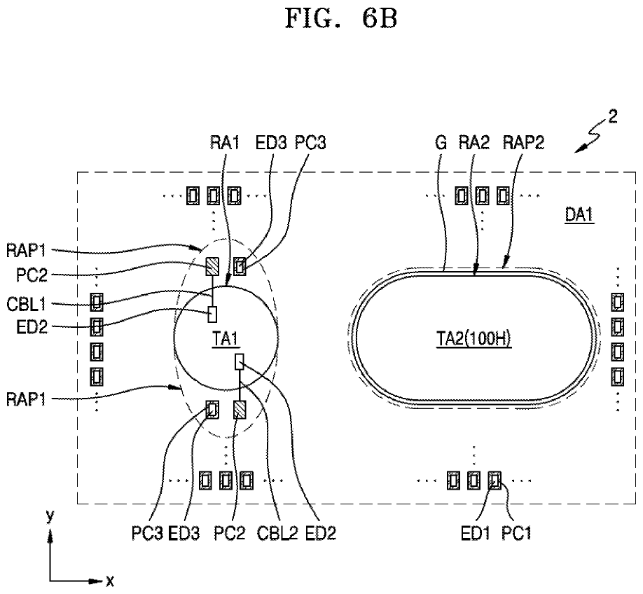

FIG. 6A is a plan view of a portion of a display panel 2 according to some embodiments, and FIG. 6B is a plan view of a portion of a display panel 2 according to some embodiments.

Referring to FIG. 6A, the first area RA1 and the second area RA2 are surrounded by the first display area DA1. A light-emitting diode corresponding to a sub-pixel may be arranged in each of the first display area DA1 and the first area RA1. The first area RA1 is a kind of display area, and as described with reference to FIG. 2, the first area RA1 corresponds to a second display area which may provide an image while simultaneously (or concurrently) being an area through which light used in a first component may pass. For example, the first area RA1 may include a first transmission area TA1 between second light-emitting diodes ED2. Here, a light-emitting diode in the first display area DA1 is referred to as a first light-emitting diode ED1, and a light-emitting diode in the first area RA1 is referred to as a second light-emitting diode ED2. Because the second light-emitting diode ED2 is in the first area RA1, it may prevent, reduce, or minimize recognition of the first area RA1 and the first display area DA1 as being differentiated by a user. In some embodiments, The arrangement and number of the second light-emitting diodes ED2 may be the same as the arrangement and number of the first light-emitting diodes ED1 per the same area. In other words, the resolution of the first area RA1 may be the same as the resolution of the first display area DA1. In this case, it may more effectively prevent or reduce instances of the first area RA1 and the first display area DA1 being differentiated by the user.

Each of the first light-emitting diode ED1 and the second light-emitting diode ED2 is electrically connected to a sub-pixel circuit including transistors and capacitor(s) as described above with reference to FIG. 5. Here, a sub-pixel circuit electrically connected to the first light-emitting diode ED1 is referred to as a first sub-pixel circuit PC1, and a sub-pixel circuit electrically connected to the second light-emitting diode ED2 is referred to as a second sub-pixel circuit PC2. Each of the first sub-pixel circuit PC1 and the second sub-pixel circuit PC2 may include the same transistors and capacitors as the sub-pixel circuit PC (refer to FIG. 5) described above with reference to FIG. 5.

The first sub-pixel circuit PC1 may be arranged in the first display area DA1 in which the first light-emitting diode ED1 is arranged. The second sub-pixel circuit PC2 may be arranged in an area other than the first area RA1 to increase the ratio of the area occupied by the first transmission area TA1 in the first area RA1. According to some embodiments, the second sub-pixel circuit PC2 may be arranged in a first peripheral area RAP1 around the first area RA1.

The first peripheral area RAP1 may be between the first area RA1 and the first display area DA1. The first peripheral area RAP1 may be on one side or both sides of the first area RA1. According to some embodiments, as shown in FIG. 6A, the first peripheral areas RAP1 may respectively be on both sides of the first area RA1 with the first area RA1 therebetween. The first peripheral areas RAP1 may respectively be on both sides of the first area RA1 in a first direction (e.g., a horizontal direction, ±x direction). According to some embodiments, as shown in FIG. 6B, the first peripheral areas RAP1 may respectively be on both sides of the first area RA1 in a second direction (e.g., a vertical direction, ±y direction). Each of FIGS. 6A and 6B illustrates that the first peripheral areas RAP1 are arranged to partially surround the periphery of the first area RA1, but embodiments according to the present disclosure are not limited thereto. According to some embodiments, the first peripheral area RAP1 may entirely surround the first area RA1.

The second sub-pixel circuit PC2 may be in the first peripheral area RAP1. The second sub-pixel circuits PC2 in each of the first peripheral areas RAP1 respectively on both sides of the first area RA1 may be electrically connected to the second light-emitting diode ED2 through a conductive bus line.

Referring to FIG. 6A the second sub-pixel circuit PC2 in the first peripheral area RAP1 on the left side of the first area RA1 is arranged opposite to the second area RA2 with the first area RA1 therebetween. The second sub-pixel circuit PC2 in the first peripheral area RAP1 on the right side of the first area RA1 is between the first area RA1 and the second area RA2.

The second sub-pixel circuit PC2 in the first peripheral area RAP1 on the left side of the first area RA1 may be electrically connected to a first conductive bus line CBL1 extending in the first direction (e.g., the horizontal direction, +x direction). The second sub-pixel circuit PC2 in the first peripheral area RAP1 on the right side of the first area RA1 may be electrically connected to a second conductive bus line CBL2 extending in the first direction (e.g., the horizontal direction, −x direction). Each of the first and second conductive bus lines CBL1 and CBL2 may include a transmissive conductive material. For example, each of the first and second conductive bus lines CBL1 and CBL2 may include indium tin oxide (ITO), indium zinc oxide (IZO), zinc oxide (ZnO), indium oxide (In₂O₃), indium gallium oxide (IGO), and/or aluminum zinc oxide (AZO).

Referring to FIG. 6B, the second sub-pixel circuit PC2 in the first peripheral area RAP1 on the upper side of the first area RA1 may be electrically connected to the first conductive bus line CBL1 extending in the second direction (e.g., the vertical direction, −y direction). The second sub-pixel circuit PC2 in the first peripheral area RAP1 on the lower side of the first area RA1 may be electrically connected to the second conductive bus line CBL2 extending in the second direction (e.g., the vertical direction, +y direction).

The first peripheral area RAP1 is a kind of display area (e.g., a third display area), and a light-emitting diode and a sub-pixel circuit electrically connected thereto may be arranged in the first peripheral area RAP1. Hereafter, a light-emitting diode in the first peripheral area RAP1 is referred to as a third light-emitting diode ED3, and sub-pixel circuit electrically connected to the third light-emitting diode ED3 is referred to as a third sub-pixel circuit PC3. The third sub-pixel circuit PC3 may include the same transistors and capacitors as the sub-pixel circuit PC (refer to FIG. 5) described above with reference to FIG. 5. The first to third sub-pixel circuits PC1, PC2, and PC3 may include transistors and capacitors having the same structure as each other.

The second area RA2 may include the second transmission area TA2. The second area RA2 may be an area in which a light-emitting diode and a sub-pixel circuit are not arranged, and the second area RA2 may be formed by removing a portion of each of layers in the display panel 2 corresponding to the second area RA2, for example, a display layer, an input sensing layer, and an optical functional layer. Accordingly, the second transmission area TA2 may be substantially the same as the second area RA2. For example, the area and/or shape of the second transmission area TA2 may be substantially the same as the area and/or shape of the second area RA2. In other words, the area and/or shape of the second transmission area TA2 may be substantially the same as the area and/or shape of holes in a display layer, an input sensing layer, and/or an optical functional layer. In other words, the area and/or shape of the second transmission area TA2 may be substantially the same as the area and/or shape of a hole 100H penetrating through a substrate of a display layer.

A second peripheral area RAP2 having a narrow with and surrounding the second area RA2 may be arranged around the second area RA2. Unlike the first peripheral area RAP1, the second peripheral area RAP2 may be a kind of non-display area in which a light-emitting diode is not arranged.

At least one groove G may be arranged in the second peripheral area RAP2 to prevent or reduce instances of impurities (e.g., contaminants, moisture, etc.) from penetrating toward the first display area DA1 through the second peripheral area RAP2. The at least one groove G may entirely surround the second area RA2 in a plan view, and may have an undercut-shaped cross-section.

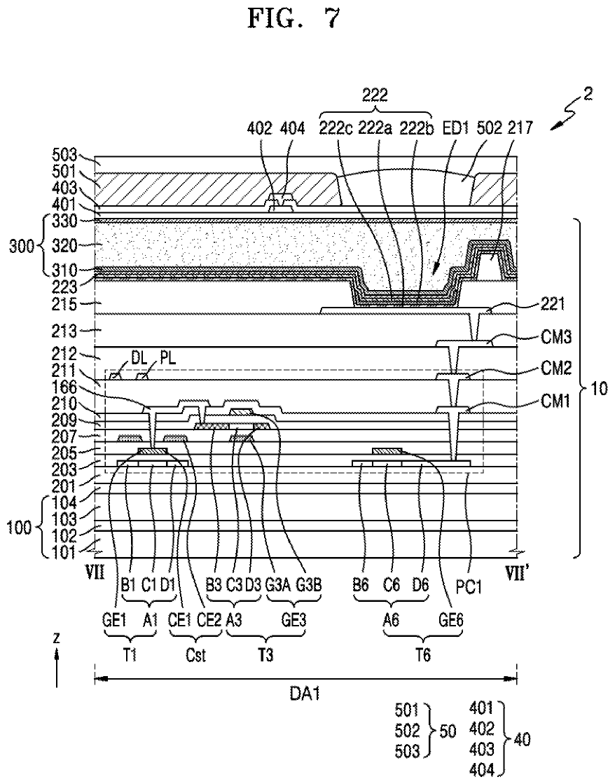

FIG. 7 is a cross-sectional view taken along a line VII-VII′ of FIG. 6A schematically illustrating a structure of the first display area DA1 of the display panel 2 according to some embodiments.

Referring to FIG. 7, the first sub-pixel circuit PC1 located on the substrate 100 and a first light-emitting diode ED1 on the first sub-pixel circuit PC1 may be in the first display area DA1.

The substrate 100 may include a first base layer 101, a first barrier layer 102, a second base layer 103, and a second barrier layer 104. The first base layer 101 is a lowermost layer of the substrate 100 and may include a bottom surface of the substrate 100, and the second barrier layer 104 is an uppermost layer of the substrate 100 and may include an upper surface of the substrate 100. For example, the bottom surface of the first base layer 101 may be the bottom surface of the substrate 100, and the upper surface of the second barrier layer 104 may be the upper surface of the substrate 100.

Each of the first and second base layers 101 and 103 may include a polymer resin. For example, each of the first and second base layers 101 and 103 may include a polymer resin, such as polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate, cellulose triacetate (TAC), cellulose acetate propionate (CAP), or the like. The polymer resin may be transparent.

Each of the first and second barrier layers 102 and 104 may prevent or reduce penetration of foreign materials. Each of the first and second barrier layers 102 and 104 may be a single layer or a multilayer, each including an inorganic material such as silicon nitride (SiNx) and/or silicon oxide (SiOx).

A buffer layer 201 may be located on the upper surface of the substrate 100. The buffer layer 201 may prevent or reduce instances of impurities penetrating into a semiconductor layer of a transistor. The buffer layer 201 may include an inorganic insulating material, such as silicon nitride, silicon oxynitride, and silicon oxide, and may include a single layer or a multilayer, each including the inorganic insulating material stated above.

The first sub-pixel circuit PC1 may be located on the buffer layer 201. The first sub-pixel circuit PC1 may include a plurality of transistors and a storage capacitor, as described above with reference to FIG. 5. In this regard, FIG. 7 illustrates the first transistor T1, the third transistor T3, the sixth transistor T6, and the storage capacitor Cst.

The first transistor T1 may include a first semiconductor layer A1 on the buffer layer 201, and a first gate electrode GE1 overlapping a channel area C1 of the first semiconductor layer A1. The first semiconductor layer A1 may include a silicon-based semiconductor material, for example, polysilicon. The first semiconductor layer A1 may include the channel area C1, a first area B1, and a second area D1, wherein the first area B1 and the second area D1 are respectively on both sides of the channel area C1. The first area B1 and the second area D1 may each be an area including a higher concentration of impurities than that of the channel area C1, and any one of the first area B1 and the second area D1 may be a source area, and the other one may correspond to a drain area.

The sixth transistor T6 may include a sixth semiconductor layer A6 on the buffer layer 201, and a sixth gate electrode GE6 overlapping a channel area C6 of the sixth semiconductor layer A6. The sixth semiconductor layer A6 may include a silicon-based semiconductor material, for example, polysilicon. The sixth semiconductor layer A6 may include the channel area C6, a first area B6, and a second area D6, wherein the first area B6 and the second area D6 are respectively on both sides of the channel area C6. The first area B6 and the second area D6 may each be an area including a higher concentration of impurities than that of the channel area C6, and any one of the first area B6 and the second area D6 may be a source area, and the other one may correspond to a drain area.

The first gate electrode GE1 and the sixth gate electrode GE6 may each include a conductive material including molybdenum (Mo), aluminum (Al), copper (Cu), titanium (Ti), or the like, and may include a single-layered or a multi-layered structure, each including the above material. A first gate insulating layer 203 for electrical insulation from the first semiconductor layer A1 and the sixth semiconductor layer A6 may be located below the first gate electrode GE1 and the sixth gate electrode GE6. The first gate insulating layer 203 may include an inorganic insulating material, such as silicon nitride, silicon oxynitride, and silicon oxide, and may include a single layer or a multilayer, each including the inorganic insulating material stated above.

The storage capacitor Cst may include the lower electrode CE1 and the upper electrode CE2, which overlap each other. According to some embodiments, the lower electrode CE1 of the storage capacitor Cst may include the first gate electrode GE1. In other words, the first gate electrode GE1 may include the lower electrode CE1 of the storage capacitor Cst. For example, the first gate electrode GE1 and the lower electrode CE1 of the storage capacitor Cst may be an integral body.

A first interlayer insulating layer 205 may be between the lower electrode CE1 and the upper electrode CE2 of the storage capacitor Cst. The first interlayer insulating layer 205 may include an inorganic insulating material, such as silicon oxide, silicon nitride, and silicon oxynitride, and may include a single-layered or multi-layered structure, each including the above inorganic insulating material.

The upper electrode CE2 of the storage capacitor Cst may include a low-resistance conductive material, such as Mo, Al, Cu, and/or T1, and may include a single-layered or multi-layered structure, each including the above material.

A second interlayer insulating layer 207 may be located on the storage capacitor Cst. The second interlayer insulating layer 207 may include an inorganic insulating material, such as silicon oxide, silicon nitride, and silicon oxynitride, and may include a single-layered or multi-layered structure, each including the above inorganic insulating material.

A third semiconductor layer A3 of the third transistor T3 may be located on the second interlayer insulating layer 207. The third semiconductor layer A3 may include an oxide-based semiconductor material. For example, the third semiconductor layer A3 may include a zinc-oxide-based material, for example, Zn oxide, In—Zn oxide, Ga—In—Zn oxide, or the like. In some embodiments, the third semiconductor layer A3 may include an In—Ga—Zn—O (IGZO), In—Sn—Zn—O (ITZO), or In—Ga—Sn—Zn—O (IGTZO) semiconductor, which include a metal such as indium (In), gallium (Ga), and tin (Sn) in ZnO.

The third semiconductor layer A3 may include a channel area C3, a first area B3, and a second area D3, wherein the first area B3 and the second area D3 are respectively on both sides of the channel area C3. One of the first area B3 and the second area D3 may be a source area, and the other one may correspond to a drain area.

The third transistor T3 may include a third gate electrode GE3 overlapping the channel area C3 of the third semiconductor layer A3. The third gate electrode GE3 may have a double gate structure including a lower gate electrode G3A located below the third semiconductor layer A3 and an upper gate electrode G3B located above the channel area C3.

The lower gate electrode G3A may be located on the same layer (e.g., the first interlayer insulating layer 205) as the upper electrode CE2 of the storage capacitor Cst. The lower gate electrode G3A may include the same material as that of the upper electrode CE2 of the storage capacitor Cst.

The upper gate electrode G3B may be located above the third semiconductor layer A3 with a second gate insulating layer 209 therebetween. The second gate insulating layer 209 may include an inorganic insulating material, such as silicon oxide, silicon nitride, and silicon oxynitride, and may include a single-layered or multi-layered structure, each including the above inorganic insulating material.

A third interlayer insulating layer 210 may be located on the upper gate electrode G3B. The third interlayer insulating layer 210 may include an inorganic insulating material such as silicon oxynitride, and may include a single-layered or multi-layered structure, each including the above inorganic insulating material.

FIG. 7 illustrates that the upper electrode CE2 of the storage capacitor Cst is located on the same layer as the lower gate electrode G3A of the third gate electrode GE3, but embodiments according to the present disclosure are not limited thereto. According to some embodiments, the upper electrode CE2 of the storage capacitor Cst may be located on the same layer as the third semiconductor layer A3, and may include the same material as the material of the first area B3 and the second area D3 of the third semiconductor layer A3.

The first transistor T1 and the third transistor T3 may be electrically connected to each other through the node connection line 166. The node connection line 166 may be located on the third interlayer insulating layer 210. One side of the node connection line 166 may be connected to the first gate electrode GE1 of the first transistor T1, and the other side of the node connection line 166 may be connected to the first area B3 of the third semiconductor layer A3 of the third transistor T3.

The node connection line 166 may include Al, Cu, and/or T1, and may include a single layer or a multilayer, each including the above material. For example, the node connection line 166 may have a three-layered structure of titanium layer/aluminum layer/titanium layer.

A first organic insulating layer 211 may be located on the node connection line 166. The first organic insulating layer 211 may include an organic insulating layer. The organic insulating material may include acrylic, benzocyclobutene (BCB), PI, hexamethyldisiloxane (HMDSO), or the like.

The data line DL and the driving voltage line PL may be located on the first organic insulating layer 211. The data line DL and the driving voltage line PL may each include Al, Cu, and/or T1, and may include a single layer or a multilayer, each including the above material. For example, the data line DL and the driving voltage line PLmay each have a three-layered structure of titanium layer/aluminum layer/titanium layer.

FIG. 7 illustrates that the data line DL and the driving voltage line PL are located on the same layer (e.g., the first organic insulating layer 211), but according to some embodiments, the data line DL and the driving voltage line PL may be located on different layers from each other.

A second organic insulating layer 212 may be located on the first organic insulating layer 211, and a third organic insulating layer 213 may be located on the second organic insulating layer 212. Each of the second organic insulating layer 212 and the third organic insulating layer 213 may include an organic insulating material, such as BCB, PI, or HMDSO.

A first electrode 221 of the first light-emitting diode ED1 may be located on the third organic insulating layer 213. The first electrode 221 may be electrically connected to the sixth transistor T6 through first to third connection metals CM1, CM2, and CM3. The first connection metal CM1 may be formed on the same layer as the node connection line 166, and may include the same material as that of the node connection line 166. The second connection metal CM2 may be formed on the same layer as the data line DL and/or the driving voltage line PL, and may include the same material as that of the data line DL and/or the driving voltage line PL. The third connection metal CM3 may include the same material as the material of the first and second conductive bus lines CBL1 and CBL2 described above with reference to FIG. 6A, for example, a transparent conductive material.

The first electrode 221 of the first light-emitting diode ED1 may include a reflective film including silver (Ag), magnesium (Mg), Al, platinum (Pt), palladium (Pd), gold (Au), nickel (Ni), neodymium (Nd), iridium (Ir), chromium (Cr), or a compound thereof. According to some embodiments, the first electrode 221 may further include a conductive oxide layer on and/or below the reflective film described above. The conductive oxide layer may include ITO, IZO, ZnO, In₂O₃, IGO, and/or AZO. For example, the first electrode 221 may have a multi-layered structure including an ITO layer, an Ag layer, and an ITO layer.

A bank layer 215 may be located on the first electrode 221. The bank layer 215 may overlap the first electrode 221 and include a bank hole for defining an emission area, but may cover an edge of the first electrode 221. The bank layer 215 may include an organic insulating material, such as PI. Alternatively, the bank layer 215 may include a light-blocking material. For example, the bank layer 215 have a black color. For example, the bank layer 215 may include a PI-based binder, and a pigment in which red, green, and blue colors are mixed with each other. Alternatively, the bank layer 215 may include a cardo-based binder resin, and a mixture of a lactam black pigment and a blue pigment. Alternatively, the bank layer 215 may include carbon black. The bank layer 215 may prevent or reduce reflection of external light together with the optical functional layer 50, and may improve the contrast of the display layer 10 of the display panel 2.

A spacer 217 may be located on the bank layer 215. The spacer 217 may be formed together with the bank layer 215 in the same operation, or may be individually formed in a separate operation. According to some embodiments, the spacer 217 may include an organic insulating material, such as PI.

An intermediate layer 222 includes an emission layer 222b. The intermediate layer 222 may include a first common layer 222a located below the emission layer 222b and/or a second common layer 222c located on the emission layer 222b. The emission layer 222b may include a polymer organic material or a low-molecular-weight organic material, which emits light of a certain color (red, green, or blue). According to some embodiments, the emission layer 222b may include an inorganic material or a quantum dot.

The second common layer 222c may include an electron transport layer (ETL) and/or an electron injection layer (EIL). The first common layer 222a and the second common layer 222c may each include an organic material.

The emission layer 222b may be formed in the first display area DA1 through a bank hole of the bank layer 215 to overlap the first electrode 221. On the other hand, an organic material layer of an intermediate layer 222, for example, the first common layer 222a and the second common layer 222c, may entirely cover the first display area DA1.

The intermediate layer 222 may have a single-stacked structure including a single emission layer, or may have a tandem structure, which is a multi-stacked structure including a plurality of emission layers. When the intermediate layer 222 has a tandem structure, a charge generation layer may be arranged between adjacent stacks of the multi-stacked structure.

A second electrode 223 may include a conductive material having a low work function. For example, the second electrode 223 may include a (semi)transparent layer including Ag, Mg, Al, Pt, Pd, Au, Ni, Nd, Ir, Cr, lithium (Li), calcium (Ca), alloys thereof, or the like. Alternatively, the second electrode 223 may further include a layer, such as ITO, IZO, ZnO, or In₂O₃, above the (semi)transparent layer including the above-stated material. The second electrode 223 may entirely cover the first display area DA1.

According to some embodiments, a capping layer including an inorganic material or an organic material may further be included on the second electrode 223. A lithium fluoride (LiF) layer may be further located on the second electrode 223.

The first light-emitting diode ED1 may be covered with an encapsulation layer 300. The encapsulation layer 300 may include at least one organic encapsulation layer and at least one inorganic encapsulation layer. According to some embodiments, FIG. 7 illustrates that the encapsulation layer 300 includes a first inorganic encapsulation layer 310, a second inorganic encapsulation layer 330, and an organic encapsulation layer 320 between the first and third inorganic encapsulation layers 310 and 330.

The first inorganic encapsulation layer 310 and the second inorganic encapsulation layer 330 may each include at least one inorganic material from among aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may each be a single layer or a multilayer, each including the material described above. The organic encapsulation layer 320 may include a polymer-based material. The polymer-based material may include an acrylic resin, an epoxy resin, polyimide, polyethylene, or the like. According to some embodiments, the organic encapsulation layer 320 may include acrylate.

The input sensing layer 40 may be located on the encapsulation layer 300 of the display layer 10. The input sensing layer 40 may include a first insulating layer 401, a first conductive layer 402, a second insulating layer 403, and a second conductive layer 404. The input sensing layer 40 may include a touch electrode, and the first conductive layer 402 and/or the second conductive layer 404 of the input sensing layer 40 may include a touch electrode. According to some embodiments, the second conductive layer 404 may include a certain pattern (e.g., a mesh pattern) corresponding to each of a plurality of touch electrodes, and the first conductive layer 402 may include a connection electrode connecting adjacent touch electrodes to each other.

The optical functional layer 50 may include a black matrix 501, a color filter 502, and an overcoat layer 503. The black matrix 501 may overlap the pattern (e.g., the mesh pattern) of the touch electrode of the optical functional layer 50. The black matrix 501 may include a light-blocking material.

The color filter 502 may have a color corresponding to light emitted by the first light-emitting diode ED1. For example, the color filter 502 may include red, green, or blue pigments or dyes.

The overcoat layer 503 may include a transparent material (e.g., a transmissive material). The overcoat layer 503 may include an organic insulating material, such as a silicone-based resin, an acryl-based resin, an epoxy-based resin, PI, polyethylene, or the like. The overcoat layer 503 may overlap the black matrix 501 and the color filter 502.

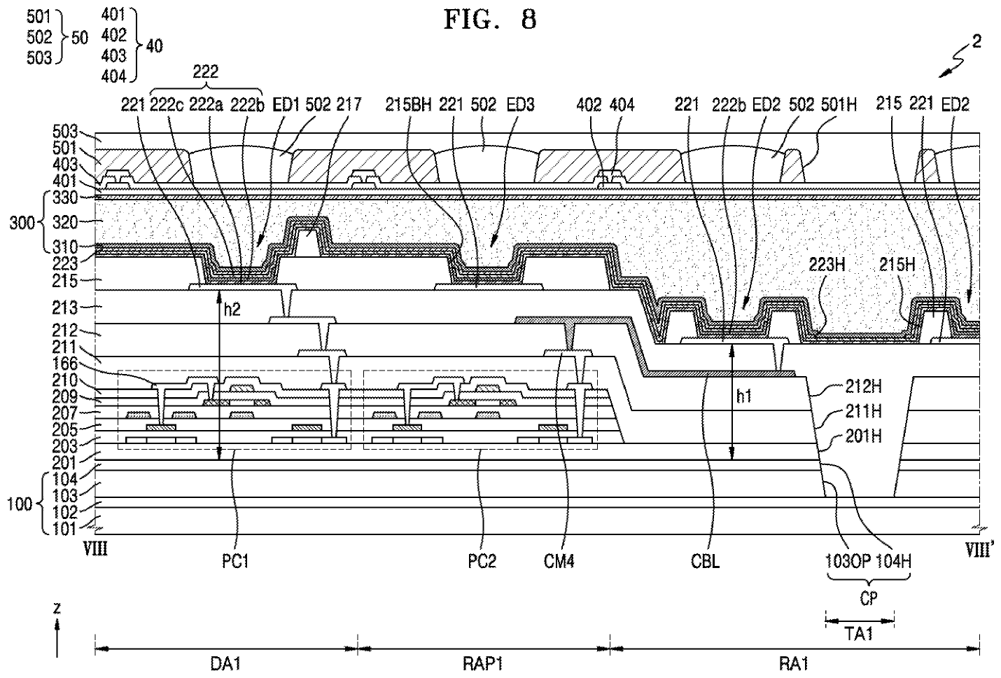

FIG. 8 is a cross-sectional view taken along a line VII-VIII′ of FIG. 6A, illustrating the display panel 2 according to some embodiments.

Referring to the first display area DA1 of FIG. 8, the first sub-pixel circuit PC1 is located on the substrate 100, and the first sub-pixel circuit PC1 is electrically connected to the first light-emitting diode ED1. The encapsulation layer 300, the input sensing layer 40, and the optical functional layer 50 are located on the first light-emitting diode ED1, and the structures thereof are the same as descriptions already given with reference to FIG. 7.

Referring to the first area RA1 of FIG. 8, a second light-emitting diode ED2 is arranged. The second light-emitting diode ED2 may include the first electrode 221 of which an edge is covered by the bank layer 215, the emission layer 222b overlapping the first electrode 221 through a bank hole of the bank layer 215, and the second electrode 223 on the emission layer 222b. As described above, the first and second common layers 222a and 222c may be between the first electrode 221 and the second electrode 223.

The second sub-pixel circuit PC2 for an operation (e.g., on, off, or the like) of the second light-emitting diode ED2 may be arranged in the first peripheral area RAP1 between the first area RA1 and the first display area DA1. In some embodiments, as shown in FIG. 8, the second sub-pixel circuit PC2 may overlap the third light-emitting diode ED3. The second sub-pixel circuit PC2 may have the same structure as that of the first sub-pixel circuit PC1 (refer to FIG. 7) described with reference to FIG. 7.

The second sub-pixel circuit PC2 and the second light-emitting diode ED2 may be electrically connected to each other through a conductive bus line CBL extending from the first peripheral area RAP1 toward the first area RA1. For example, the conductive bus line CBL may be connected to the second sub-pixel circuit PC2 through a fourth connection metal CM4 in the first peripheral area RAP1. FIG. 8 illustrates that the conductive bus line CBL is located on the second organic insulating layer 212, but according to some embodiments, the conductive bus line CBL may be below the second organic insulating layer 212, for example, on the first organic insulating layer 211. The conductive bus line CBL may include a transmissive material.

The substrate 100 may include a concave portion CP in the first area RA1. The concave portion CP may correspond to the first transmission area TA1. The concave portion CP may correspond to an area between two adjacent second light-emitting diodes ED2. The concave portion CP may have a shape recessed into a sub-layer of the substrate 100. For example, the concave portion CP may have a shape recessed into the second barrier layer 104 and the second base layer 103 of the substrate 100. In other words, each of a hole 104H of the second barrier layer 104 and an opening 1030P of the second base layer 103 may correspond to a portion of the concave portion CP. FIG. 8 illustrates that the opening 1030P of the second base layer 103 penetrates from a upper surface to a bottom surface of the second base layer 103, similarly to that the hole 104H of the second barrier layer 104 penetrates from a upper surface to a bottom surface of the second barrier layer 104, but embodiments according to the present disclosure are not limited thereto. According to some embodiments, the opening 1030P of the second base layer 103 may have a shape of a blind hole that does not penetrate from the upper surface to the bottom surface of the second base layer 103. Here, a hole may represent a through hole, and an opening may be a blind hole or a through hole.

Layers formed on the concave portion CP of the substrate 100, for example, the buffer layer 201, the first organic insulating layer 211, and the second organic insulating layer 212, may respectively include holes 201H, 211H, and 212H, which overlap the concave portion CP. The concave portion CP of the substrate 100 and the holes 201H, 211H, and 212H of the buffer layer 201, the first organic insulating layer 211, and the second organic insulating layer 212 may be at least partially filled with an organic insulating material. For example, a portion of the third organic insulating layer 213 may at least partially fill the concave portion CP of the substrate 100 and the holes 201H, 211H, and 212H of the buffer layer 201, the first organic insulating layer 211, and the second organic insulating layer 212. In some embodiments, a portion of the third organic insulating layer 213 may overlap the concave portion CP, and may be in contact with the upper surface of the first barrier layer 102 through the concave portion CP.

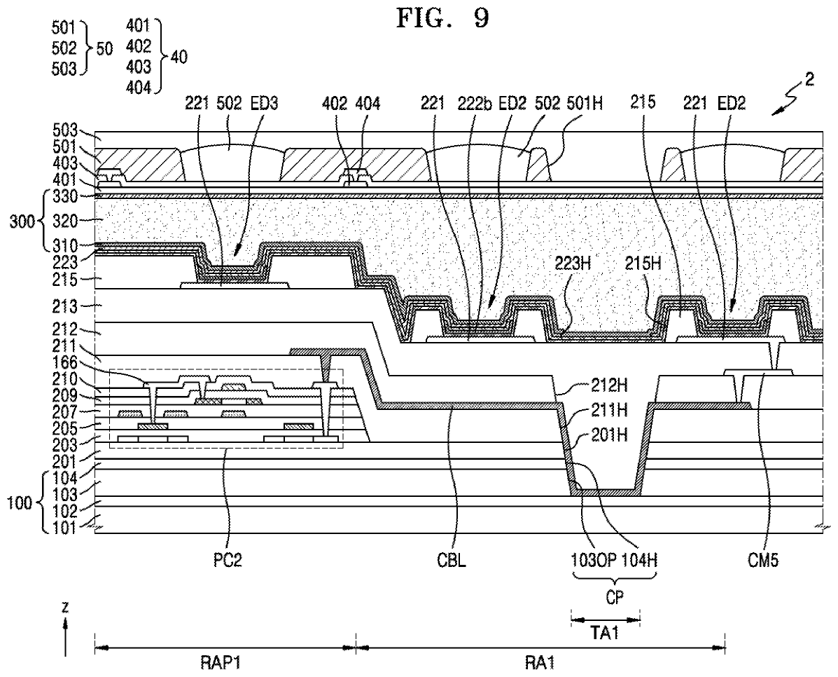

Portions of inorganic insulating layers between the buffer layer 201 and the first organic insulating layer 211, the portions corresponding to the first area RA1, may be removed. According to some embodiments, portions of the first gate insulating layer 203, the first interlayer insulating layer 205, the second interlayer insulating layer 207, the second gate insulating layer 209, and the third interlayer insulating layer 210, the portions corresponding to the first area RA1, may be removed. Accordingly, as shown in FIG. 8, an end portion of each of the first gate insulating layer 203, the first interlayer insulating layer 205, the second interlayer insulating layer 207, the second gate insulating layer 209, and the third interlayer insulating layer 210 may surround the concave portion CP of the substrate 100. In this regard, FIG. 9 illustrates that an end portion of each of the first gate insulating layer 203, the first interlayer insulating layer 205, the second interlayer insulating layer 207, the second gate insulating layer 209, and the third interlayer insulating layer 210 is between the first area RA1 and the first peripheral area RAP1. The first organic insulating layer 211 may be in direct contact with the buffer layer 201 in the first area RA1 around the concave portion CP.

Unlike the first display area DA1, sub-pixel circuits are not provided in the first area RA1, and the first gate insulating layer 203, the first interlayer insulating layer 205, the second interlayer insulating layer 207, the second gate insulating layer 209, and/or the third interlayer insulating layer 210 may not be in the first area RA1. Accordingly, a first height h1 from the substrate 100 to the first electrode 221 of the second light-emitting diode ED2 in the first area RA1 may be less than a second height h2 from the substrate 100 in the first display area DA1 to the first electrode 221 of the first light-emitting diode ED1.

The bank layer 215 may include bank hole 215BH overlapping the first electrode 221 of each of the first to third light-emitting diodes ED1, ED2, and ED3. The bank layer 215 may include a hole 215H overlapping the concave portion CP of the substrate 100. The second electrode 223 of each of the first to third light-emitting diodes ED1, ED2, and ED3 may also include a hole 223H overlapping the concave portion CP of the substrate 100. Accordingly, the light transmittance of the first transmission area TA1 may be improved.

Unlike the second electrode 223, the first and second common layers 222a and 222c may not include a hole. In other words, the first and second common layers 222a and 222c may overlap the concave portion CP. The first inorganic encapsulation layer 310, the organic encapsulation layer 320, and the second inorganic encapsulation layer 330 of the encapsulation layer 300, and the first and second insulating layers 401 and 403 of the input sensing layer 40 may overlap the concave portion CP.

The black matrix 501 of the optical functional layer 50 may include a hole 501H overlapping the concave portion CP, and the hole 501H of the black matrix 501 may be at least partially filled with a portion of the overcoat layer 503.

FIG. 9 is a cross-sectional view of the display panel 2 according to some embodiments, illustrating cross-sections of the first area RA1 and the first peripheral area RAP1. The structures of the first area RA1 and the first peripheral area RAP1 shown in FIG. 9 are the same as the structures of the first area RA1 and the first peripheral area RAP1 described above with reference to FIG. 8 except for the conductive bus line CBL, and thus, a difference thereof is mainly described below.

Referring to FIG. 9, the second sub-pixel circuit PC2 in the first peripheral area RAP1 may be electrically connected to the first electrode 221 of the second light-emitting diode ED2 through the conductive bus line CBL extending from the first peripheral area RAP1 to the first area RA1. At least a portion of the conductive bus line CBL may be on the first organic insulating layer 211, and may be electrically connected to the first electrode 221 of the second light-emitting diode ED2 through a fifth connection metal CM5 in the first area RA1.

The substrate 100 may include the concave portion CP, and an insulating layer on the substrate 100, for example, the buffer layer 201 and the first organic insulating layer 211, may respectively include holes 201H and 211H, which overlap the concave portion CP.

A portion of the conductive bus line CBL may overlap the concave portion CP of the substrate 100. For example, as shown in FIG. 9, the conductive bus line CBL may extend from the upper surface of the first organic insulating layer 211 to the bottom surface of the concave portion CP (e.g., the upper surface of the first barrier layer 102) by passing by a side surface of the first organic insulating layer 211, a side surface of the buffer layer 201, and a side surface of the concave portion CP.

In FIGS. 8 and 9, the first peripheral area RAP1 arranged on the left side of the first area RA1 is mainly described, but embodiments according to the present disclosure are not limited thereto. The first peripheral area RAP1 on the right side of the first area RA1 may also have the same structure as the structure described with reference to FIGS. 8 and 9. In other words, the conductive bus line CBL described with reference to FIGS. 8 and 9 may correspond to the first conductive bus line CBL1 and/or the second conductive bus line CBL2 described with reference to FIG. 6A. Therefore, for example, “a portion of the conductive bus line CBL overlaps the concave portion CP” described with reference to FIG. 9 may indicate that “the first conductive bus line CBL1 and/or the second conductive bus line CBL2 overlap the concave portion CP” described with reference to FIG. 6A.

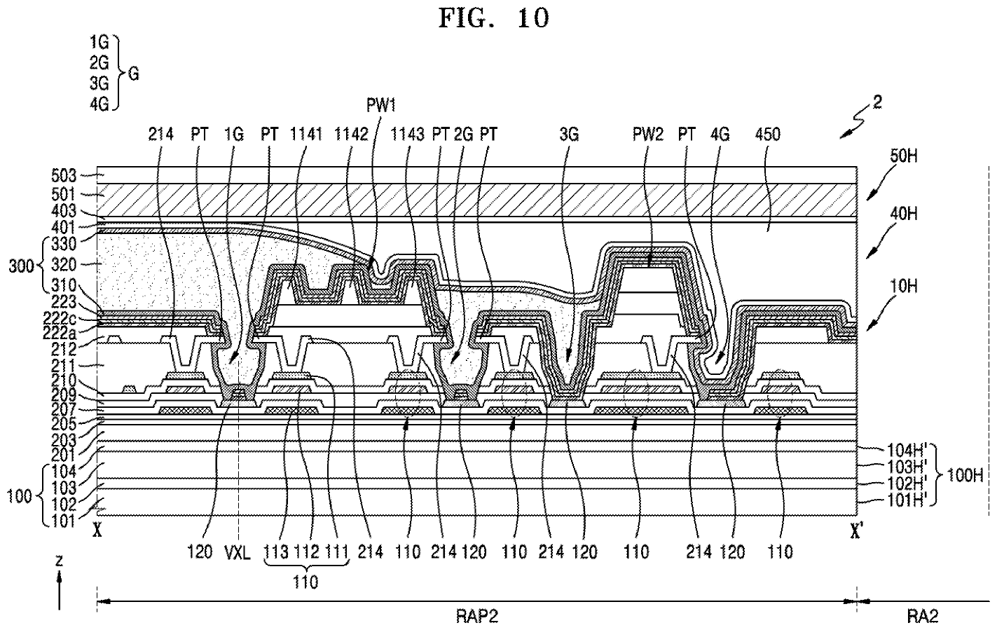

FIG. 10 is a cross-sectional view taken along a line X-X′ of FIG. 6A, illustrating the display panel 2 according to some embodiments.

Referring to FIG. 10, the substrate 100 may include a hole 100H in the second area RA2. The hole 100H of the substrate 100 may be formed to penetrate through the bottom surface from the upper surface of the substrate 100. For example, as shown in FIG. 10, a hole 101H′ of the first base layer 101, a hole 102H′ of the first barrier layer 102, a hole 103H′ of the second base layer 103, and a hole 104H′ of the second barrier layer 104, which overlap each other, may form the hole 100H of the substrate 100.

Referring to FIGS. 6 and 10, at least one groove G may be in the second peripheral area RAP2 surrounding the second area RA2. In this regard, FIG. 10 illustrate a first groove 1G, a second groove 2G, a third groove 3G, and a fourth groove 4G, but embodiments according to the present disclosure are not limited thereto. The number of grooves G may be variously changed.

The first to fourth grooves 1G, 2G, 3G, and 4G may be arranged to be spaced apart from each other in one direction, for example, a direction from the second peripheral area RAP2 toward the second area RA2. The first to fourth grooves 1G, 2G, 3G, and 4G may each have a closed loop shape surrounding the second area RA2 as described above with reference to FIGS. 6A and 6B.

The groove G may penetrate through at least one insulating layer formed on the buffer layer 201. The at least one insulating layer in which the groove G is formed includes the first organic insulating layer 211, but may also include an insulating layer(s) below the first organic insulating layer 211. In this regard, FIG. 10 illustrates that each of the first to fourth grooves 1G, 2G, 3G, and 4G is formed by penetrating through the second gate insulating layer 209, the third interlayer insulating layer 210, and the first organic insulating layer 211. The groove G, for example, the first to fourth grooves 1G, 2G, 3G, and 4G, may be formed by removing a portion of each of the second gate insulating layer 209, the third interlayer insulating layer 210, and the first organic insulating layer 211 through etching.

A lower layer 120 is directly below the groove G. The lower layer 120 may function as an etch stopper in an etching operation for forming the groove G. Accordingly, the bottom surface of the groove G may be the upper surface of the lower layer 120. In this regard, FIG. 10 illustrates that the lower layer 120 is below each of the first to fourth grooves 1G, 2G, 3G, and 4G, and a bottom surface of each of the first to fourth grooves 1G, 2G, 3G, and 4G is the same plane as the upper surface of the lower layer 120.

The lower layer 120 may be on the second interlayer insulating layer 207, and may be formed together with the third semiconductor layer A3 (refer to FIG. 7) described with reference to FIG. 7 in the same operation. The lower layer 120 may include the same material as the material of the third semiconductor layer A3, for example, an oxide-based semiconductor material. Similarly to the groove G, in the plan view, the lower layer 120 may have a closed loop shape surrounding the second area RA2.

At least one of the grooves G (e.g., at least one of the first to fourth grooves 1G, 2G, 3G, or 4G) may include a tip PT. According to some embodiments, as shown in FIG. 10, the first groove 1G, the second groove 2G, and the fourth groove 4G may each have an undercut shape. For example, the first groove 1G may include an undercut shape on each of both sides of a virtual vertical line VXL passing through the center of the first groove 1G. On the contrary, the fourth groove 4G may have an undercut shape on one side thereof.

The tip PT for implementing the undercut shape of each of the first groove 1G, the second groove 2G, and the fourth groove 4G may be provided on a metal pattern layer 214 directly located on the first organic insulating layer 211. According to some embodiments, the metal pattern layer 214 may have a multi-layered structure of titanium layer/aluminum layer/titanium layer.

The metal pattern layer 214 may be arranged on at least one side of the groove G as a center. For example, the metal pattern layer 214 may be on each of both sides of a virtual vertical line VXL passing through the center of the first groove 1G, and an end portion of each of the metal pattern layers 214 may protrude toward the center of the first groove 1G to form the tip PT. The tip PT is a kind of eaves portion, and may protrude toward the center of the first groove 1G by passing through an inner side surface of the first organic insulating layer 211.

Similarly, the metal pattern layer 214 may be on each of both sides of the second groove 2G, and an end portion of each of the metal pattern layers 214 protrude toward the center of the second groove 2G to form the tip PT.

The fourth groove 4G may include one tip PT. The tip PT may be on one side of the fourth groove 4G, for example, one side adjacent to a second partition wall PW2. The metal pattern layer 214 may be on one side of the fourth groove 4G, and an end portion of the metal pattern layer 214 may form the tip PT by passing by the first organic insulating layer 211 which forms an inner side surface of the fourth groove 4G and protruding toward the center of the fourth groove 4G. The third groove 3G may not include a tip, and accordingly, the third groove 3G does not have an undercut shape.

Some of layers of a light-emitting diode, for example, the first and second common layers 222a and 222c, which include organic materials, may be cut by the groove G including the tip PT. The second electrode 223 may be cut by the groove G including the tip PT. In this regard, FIG. 10 illustrates that the first and second common layers 222a and 222c, and the second electrode 223 may each be separated into a plurality of portions spaced apart from each other by the tips PT of the first groove 1G, the second groove 2G, and the fourth groove 4G. Any one of portions of the first and second common layers 222a and 222c, the portions being spaced apart from each other, may be on the bottom surface of the first groove 1G, the second groove 2G, or the fourth groove 4G in a state of being separated and spaced apart from other portions of the first and second common layers 222a and 222c.

A metal dummy stack 110 may be arranged around the groove G. For example, the metal dummy stack 110 may be on each of both sides of the groove G. The metal dummy stack 110 is a kind of mound, and the depth of the groove G may be increased. According to some embodiments, FIG. 10 illustrates that the metal dummy stack 110 includes three metal layers, for example, first to third metal layers 111, 112, and 113, with insulating layers therebetween.

The first to third metal layers 111, 112, and 113 may be located on the same layer as the electrodes of the transistors and the storage capacitor described with reference to FIG. 7, and may include the same material as that of the electrodes of the transistors and the storage capacitor. For example, the first metal layer 111 may be on the same layer as the node connection line 166 (refer to FIG. 7), and may include the same material as that of the node connection line 166. The second metal layer 112 may be on the same layer as the upper gate electrode G3B (refer to FIG. 7), which is a sub layer of the third gate electrode GE3, and may include the same material as that of the upper gate electrode G3B. The third metal layer 113 may be on the same layer as the upper electrode CE2 of the storage capacitor Cst (refer to FIG. 7) and/or the lower gate electrode G3A (refer to FIG. 7), which is a sub layer of the third gate electrode GE3, and may include the same material as the material of the upper electrode CE2 of the storage capacitor Cst and/or the lower gate electrode G3A. FIG. 10 illustrates that the metal dummy stack 110 includes three metal layers with insulating layers therebetween, but embodiments according to the present disclosure are not limited thereto. According to some embodiments, the number of metal layers of the metal dummy stack 110 may be less than three or more than three.

Some of grooves G, for example, the third groove 3G, may not include the tip PT. The third groove 3G may be used for monitoring the organic encapsulation layer 320 of the encapsulation layer 300.

At least one partition wall other than the grooves G described above may be in the second peripheral area RAP2, and in this regard, FIG. 10 illustrates a first partition wall PW1 and the second partition wall PW2. The grooves G (e.g., the first to fourth grooves 1G, 2G, 3G, and 4G) may be spaced apart from each other in the second peripheral area RAP2. The first groove 1G may be between the first partition wall PW1 and the first display area DA1 (refer to FIGS. 6A and 6B). The second groove 2G and the third groove 3G may be between the first partition wall PW1 and the second partition wall PW2, and the fourth groove 4G may be between the second partition wall PW2 and the hole 100H of the substrate 100.

The groove G between the first partition wall PW1 and the second partition wall PW2 may be covered with the organic encapsulation layer 320. In this regard, FIG. 10 illustrates that the second groove 2G and the third groove 3G are covered with the organic encapsulation layer 320 in an area between the first partition wall PW1 and the second partition wall PW2. In a comparative example of the disclosure in which the groove G between the first partition wall PW1 and the second partition wall PW2, for example, the second groove 2G and the third groove 3G, may not be covered with the organic encapsulation layer 320, inorganic insulating layers, such as the first inorganic encapsulation layer 310 and the second inorganic encapsulation layer 330, may be in contact with each other on the second groove 2G and the third groove 3G. When the area of a contact area of the first inorganic encapsulation layer 310 and the second inorganic encapsulation layer 330 on the second groove 2G and the third groove 3G relatively increases, cracks are easily generated at a contact portion between the first and second inorganic encapsulation layers 310 and 330 due to a uneven structure of the second groove 2G and the third groove 3G or the like. The cracks reduce the quality of the display layer 10 of the display panel 2. However, according to some embodiments, the organic encapsulation layer 320 is made to cover the groove G, for example, the second groove 2G and the third groove 3G, between the first partition wall PW1 and the second partition wall PW2, and thus, the problem described above may be prevented, reduced, or minimized.

The first inorganic encapsulation layer 310 of the encapsulation layer 300 may continuously cover an inner side surface of the groove G. The organic encapsulation layer 320 may overlap the first groove 1G, and the second and third grooves 2G and 3G between the first partition wall PW1 and the second partition wall PW2. The second inorganic encapsulation layer 330 may be in contact with the first inorganic encapsulation layer 310 in an area in which the organic encapsulation layer 320 is not arranged. For example, the second inorganic encapsulation layer 330 may be in contact with the first inorganic encapsulation layer 310 on any one protrusion of the first partition wall PW1. The second inorganic encapsulation layer 330 may be in contact with the first inorganic encapsulation layer 310 in an area between the second partition wall PW2 and the hole 100H of the substrate 100.

The first partition wall PW1 may include a plurality of protrusions to control the flow of monomers when the organic encapsulation layer 320 is formed. According to some embodiments, FIG. 10 illustrates that the first partition wall PW1 includes first to third protrusions 1141, 1142, and 1143 spaced apart from each other, but the number of protrusions may be two. The first to third protrusions 1141, 1142, and 1143 may be formed to have the same height, but embodiments according to the present disclosure are not limited thereto. The height of the third protrusion 1143 arranged relatively close to the second area RA2 (e.g., a vertical distance from the upper surface of the substrate 100 to an upper surface of the third protrusion 1143) may be greater than the height of the first protrusion 1141 arranged relatively close to the first display area DA1 (e.g., a vertical distance from the upper surface of the substrate 100 to an upper surface of the first protrusion 1141). For example, the height of the third protrusion 1143 may be substantially equal to the height of the second partition wall PW2 (e.g., a vertical distance from the upper surface of the substrate 100 to an upper surface of the second partition wall PW2).

The first and second insulating layers 401 and 403 of the input sensing layer 40 may be located on the encapsulation layer 300. The optical functional layer 50 may be located on the input sensing layer 40. Because the second peripheral area RAP2 is a kind of non-display area, the black matrix 501 may be arranged in the second peripheral area RAP2, and the overcoat layer 503 may be located on the black matrix 501. A planarization organic layer 450 may be between the first insulating layer 401 and the second insulating layer 403 of the input sensing layer 40. A portion of the planarization organic layer 450 may overlap a portion of the organic encapsulation layer 320. The planarization organic layer 450 may planarize the second peripheral area RAP2 by overlapping the third groove 3G and/or the second partition wall PW2 that does not overlap the organic encapsulation layer 320.

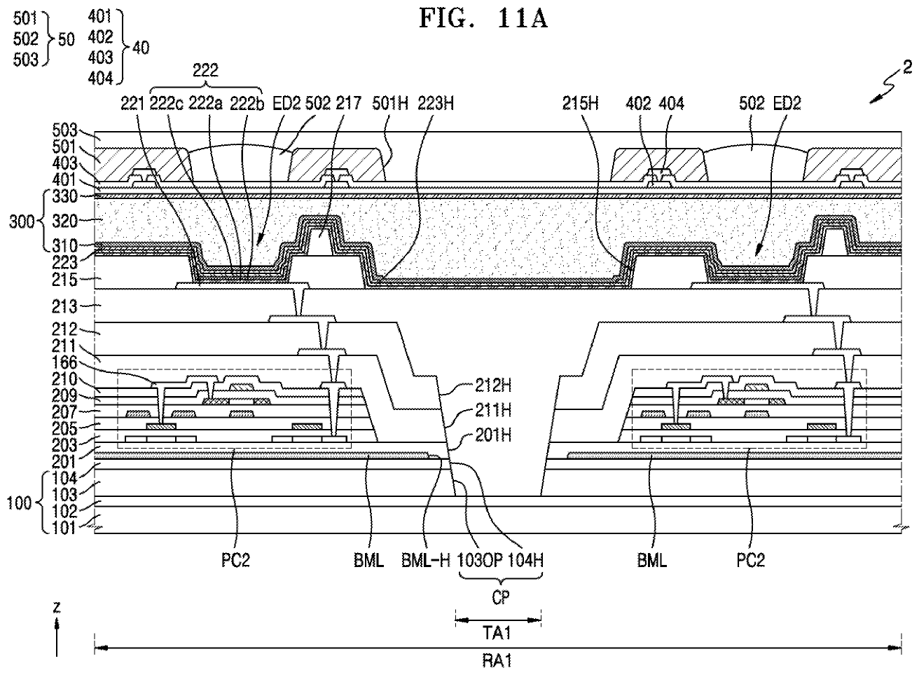

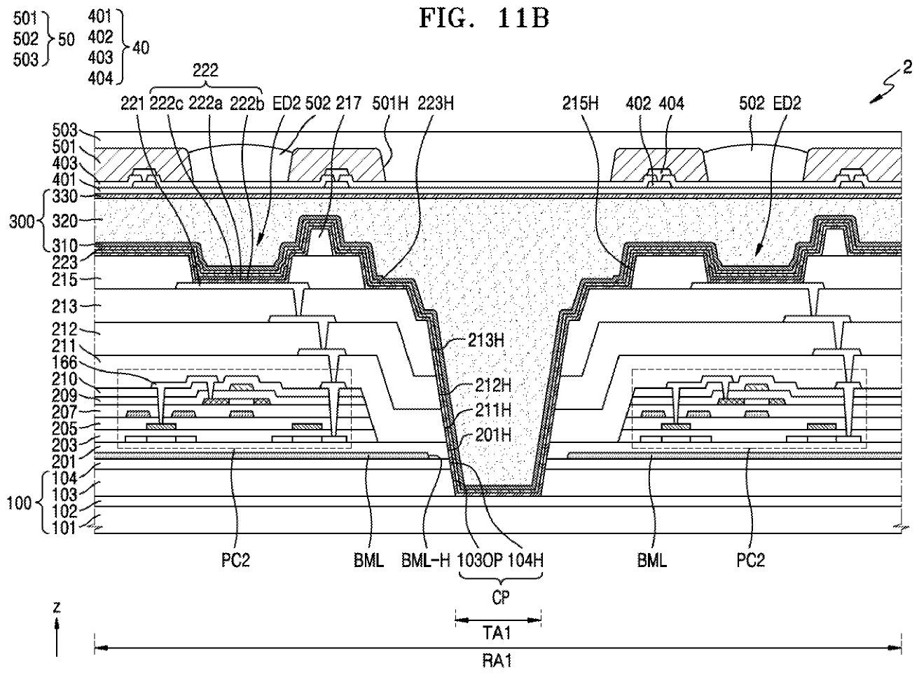

FIGS. 11A and 11B are cross-sectional views each illustrating the first area RA1 of the display panel 2 according to some embodiments. According to some embodiments described with reference to FIG. 8, the second sub-pixel circuit PC2 is described to be arranged in the first peripheral area RAP1 around the first area RA1, but according to the embodiments of FIGS. 11A and 11B, the second sub-pixel circuit PC2 may be arranged in the first area RA1. The cross-sectional structure of the second sub-pixel circuit PC2 may have the same structure as that of the first sub-pixel circuit PC1 described above with reference to FIG. 7.

The second light-emitting diodes ED2 in the first area RA1 may be arranged on the second sub-pixel circuits PC2 arranged in the first area RA1, respectively. To prevent or reduce instances of the second sub-pixel circuit PC2 being damaged by light emitted by or incident to a first component to be arranged in the first area RA1 or from being affected by light during driving, a light-blocking metal layer BML may be between the substrate 100 and the second sub-pixel circuit PC2.

The light-blocking metal layer BML may include a hole BML-H overlapping the concave portion CP of the substrate 100. In some embodiments, the area (or width) of the hole BML-H of the light-blocking metal layer BML may be greater than the area (or width) of the concave portion CP of the substrate 100.

The concave portion CP of the substrate 100 may have a shape recessed into the second barrier layer 104 and the second base layer 103. The hole 104H of the second barrier layer 104 and the opening 1030P of the second base layer 103, which overlap each other, may correspond to the concave portion CP.

Referring to FIG. 11A, layers formed on the concave portion CP of the substrate 100, for example, the buffer layer 201, the first organic insulating layer 211, and the second organic insulating layer 212 may respectively include holes 201H, 211H, and 212H, which overlap the concave portion CP. The concave portion CP of the substrate 100 and the holes 201H, 211H, and 212H of the buffer layer 201, the first organic insulating layer 211, and the second organic insulating layer 212 may be at least partially filled with an organic insulating material. For example, a portion of the third organic insulating layer 213 may at least partially fill the concave portion CP of the substrate 100 and the holes 201H, 211H, and 212H of the buffer layer 201, the first organic insulating layer 211, and the second organic insulating layer 212. In some embodiments, a portion of the third organic insulating layer 213 may be in contact with an upper surface of the first barrier layer 102 through the concave portion CP.

The second electrode 223 of the second light-emitting diode ED2 may include a hole 223H overlapping the concave portion CP of the substrate 100. Each of the first and second common layers 222a and 222c may overlap the concave portion CP. The bank layer 215 may include the hole 215H overlapping the concave portion CP of the substrate 100. Accordingly, the light transmittance of the first transmission area TA1 may be improved.

The first inorganic encapsulation layer 310, the organic encapsulation layer 320, and the second inorganic encapsulation layer 330 of the encapsulation layer 300, and the first and second insulating layers 401 and 403 of the input sensing layer 40 may overlap the concave portion CP. The black matrix 501 of the optical functional layer 50 may include the hole 501H overlapping the concave portion CP, and the hole 501H of the black matrix 501 may be at least partially filled with a portion of the overcoat layer 503.

Referring to FIG. 11B, layers formed on the concave portion CP of the substrate 100, for example, the buffer layer 201, the first organic insulating layer 211, the second organic insulating layer 212, and the third organic insulating layer 213 may respectively include holes 201H, 211H, 212H, and 213H, which overlap the concave portion CP. The concave portion CP of the substrate 100 and/or the holes 201H, 211H, 212H, and 213H of the buffer layer 201, the first organic insulating layer 211, the second organic insulating layer 212, and the third organic insulating layer 213 may be at least partially filled with an organic insulating layer. For example, a portion of the organic encapsulation layer 320 may at least partially fill the concave portion CP of the substrate 100 and/or the holes 201H, 211H, 212H, and 213H of the buffer layer 201, the first organic insulating layer 211, and the second organic insulating layer 212, and the third organic insulating layer 213.

The second electrode 223 of the second light-emitting diode ED2 may include the hole 223H overlapping the concave portion CP of the substrate 100. Each of the first and second common layers 222a and 222c may overlap the concave portion CP. For example, as shown in FIG. 11B, the first common layer 222a may be in contact with the upper surface of the first barrier layer 102 through the concave portion CP.

The bank layer 215 may include the hole 215H overlapping the concave portion CP of the substrate 100. Accordingly, the light transmittance of the first transmission area TA1 may be improved.

The first inorganic encapsulation layer 310 and the second inorganic encapsulation layer 330 of the encapsulation layer 300, and the first and second insulating layers 401 and 403 of the input sensing layer 40 may overlap the concave portion CP. The black matrix 501 of the optical functional layer 50 may include the hole 501H overlapping the concave portion CP, and the hole 501H of the black matrix 501 may be at least partially filled with a portion of the overcoat layer 503.

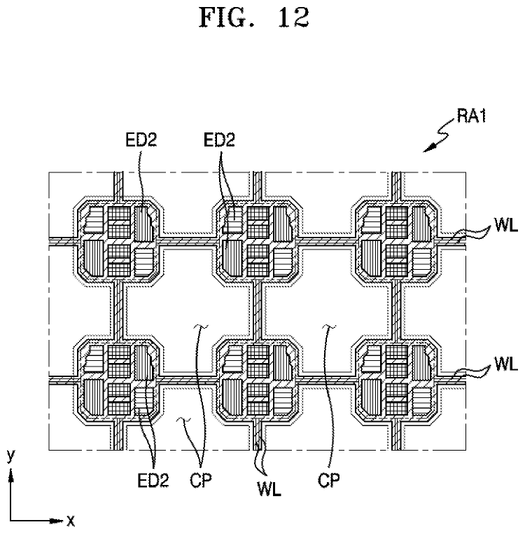

FIG. 12 is a plan view viewed from a direction perpendicular to a substrate of FIGS. 11A and 11B, schematically illustrating the first area RA1 of the display panel according to some embodiments.

Referring to FIG. 12, the second light-emitting diodes ED2 may be arranged in the first area RA1. For example, some of the second light-emitting diodes ED2 may form a group, and a plurality of groups may be spaced apart from each other. The concave portion CP of the substrate 100 described with reference to FIGS. 11A and 11B may be between the second light-emitting diode ED2 of any one group and the second light-emitting diode ED2 of the other one group.

Because a second sub-pixel circuit electrically connected to the second light-emitting diode ED2 is arranged in the first area RA1, a line WL electrically connected to the second sub-pixel circuit may also be arranged in the first area RA1. The line WL may be a signal line and a voltage line, such as a scan line, a data line, and a driving voltage line. As shown in FIG. 12, lines WL may extend in a first direction (e.g., an x direction) and a second direction (e.g., a y direction).

The concave portion CP of the substrate 100 in the first area RA1 may be spaced apart from other adjacent concave portions CP. The line WL may pass between two adjacent concave portions CP.

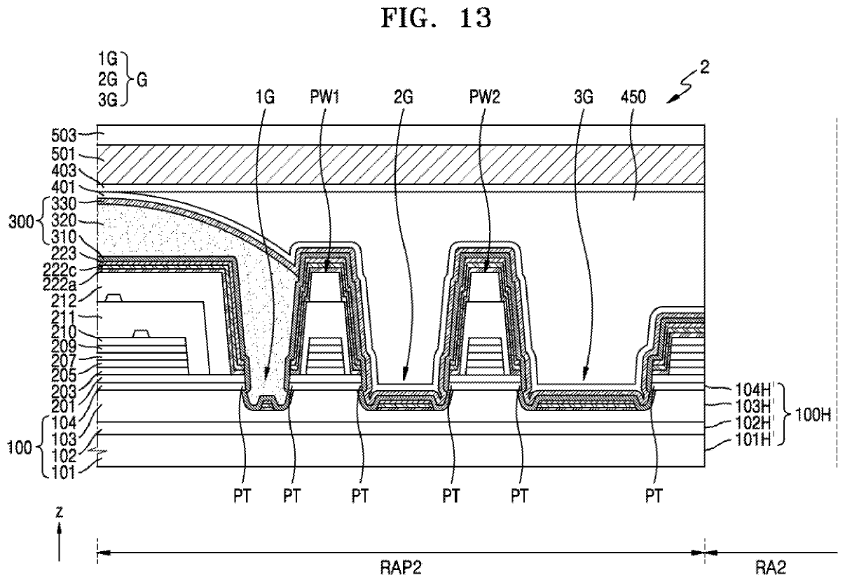

FIG. 13 is a cross-sectional view of the display panel 2 according to some embodiments, illustrating the second area RA2 and the second peripheral area RAP2. According to the embodiments described with reference to FIG. 10, the groove G is located on the upper surface of the substrate 100, but according to the embodiments shown in FIG. 13, the groove G may be formed in the substrate 100.

Referring to the second area RA2 of FIG. 13, the substrate 100 may include the hole 100H in the second area RA2. The hole 100H of the substrate 100 may be formed to penetrate through the bottom surface from the upper surface of the substrate 100. For example, as shown in FIG. 13, the hole 101H′ of the first base layer 101, the hole 102H′ of the first barrier layer 102, the hole 103H′ of the second base layer 103, and the hole 104H′ of the second barrier layer 104, which overlap each other, may form the hole 100H of the substrate 100.

Referring to the second peripheral area RAP2 of FIG. 13, at least one groove G may be formed in the substrate 100. The groove G may entirely surround the second area RA2, as described above with reference to FIGS. 6A and 6B. According to some embodiments, FIG. 13 illustrates the first groove 1G, the second groove 2G, and the third groove 3G, but embodiments according to the present disclosure are not limited thereto. The number of grooves G may be variously changed.

The first to third grooves 1G, 2G, and 3G may be arranged to be spaced apart from each other in one direction, for example, a direction from the second peripheral area RAP2 toward the second area RA2. The first to third grooves 1G, 2G, and 3G may each have a closed loop shape surrounding the second area RA2 as described above with reference to FIGS. 6A and 6B.

The groove G may penetrate through at least one of the sub-layers included in the substrate 100. The groove G may have a shape recessed into the second barrier layer 104 and the second base layer 103. The groove G, for example, the first to third grooves 1G, 2G, and 3G, may be formed by removing portions of the second barrier layer 104 and the second base layer 103 through etching. FIG. 13 illustrates that a portion of the second base layer 103 may be removed in a thickness direction of the second base layer 103 in an etching operation for forming the groove G, and in this case, the bottom surface of the groove G may be above the upper surface of the first barrier layer 102, but embodiments according to the present disclosure are not limited thereto. According to some embodiments, the bottom surface of the groove G is the upper surface of the first barrier layer 102.

At least one of the grooves G (e.g., at least one of the first to third grooves 1G, 2G, or 3G) may include a tip PT. According to some embodiments, as shown in FIG. 13, the first groove 1G, the second groove 2G, and the third groove 3G may each have an undercut shape. The first groove 1G may have an undercut-shaped cross section on each of both sides of a virtual vertical line passing through the center of the first groove 1G. Similarly, the second groove 2G and the third groove 3G may also have undercut-shaped cross sections on each of both sides of virtual vertical lines passing through the centers of the second groove 2G and the third groove 3G, respectively. An undercut shape may be implemented by the tip PT of the second barrier layer 104.

The second barrier layer 104 and the second base layer 103 may include different insulating materials. The second barrier layer 104 and the second base layer 103 may have different etch selectivities. Alternatively, the second barrier layer 104 and the second base layer 103 may be etched with different etching gases. Due to the above-described material difference and/or etching gas difference, the second barrier layer 104 may have a tip PT that protrudes more toward the center of the groove G than the inner side surface of the second base layer 103 facing the groove G.

Some of layers of a light-emitting diode, for example, the first and second common layers 222a and 222c, which include organic materials, may be cut by the groove G including the tip PT. The second electrode 223 may be cut by the groove G including the tip PT. In this regard, FIG. 13 illustrates that the first and second common layers 222a and 222c, and the second electrode 223 may each be separated into a plurality of portions spaced apart from each other by the tips PT of the first groove 1G, the second groove 2G, and the third groove 3G. Any one of portions of the first and second common layers 222a and 222c, the portions being spaced apart from each other, may be on the bottom surface of the first groove 1G, the second groove 2G, or the third groove 3G in a state of being separated and spaced apart from other portions of the first and second common layers 222a and 222c. Any one of the portions of the second electrode 223, the portions being spaced apart from each other, may be on the bottom surface of the first groove 1G, the second groove 2G, or the third groove 3G in a state of being separated and spaced apart from other portions of the second electrode 223.

At least one partition wall other than the grooves G described above may be in the second peripheral area RAP2, and in this regard, FIG. 13 illustrates the first partition wall PW1 and the second partition wall PW2. The first groove 1G may be between the first partition wall PW1 and the first display area DA1 (refer to FIGS. 6A and 6B). The second groove 2G may be between the first partition wall PW1 and the second partition wall PW2, and the third groove 3G may be between the second partition wall PW2 and the hole 100H of the substrate 100.

The first inorganic encapsulation layer 310 of the encapsulation layer 300 may continuously cover the inner surfaces of the grooves G. The organic encapsulation layer 320 may overlap the first groove 1G. The second inorganic encapsulation layer 330 may be in contact with the first inorganic encapsulation layer 310 in an area in which the organic encapsulation layer 320 is not arranged. For example, the second inorganic encapsulation layer 330 may be in contact with the first inorganic encapsulation layer 310 in an area between the first partition wall PW1 and the hole 100H of the substrate 100.

The first and second insulating layers 401 and 403 of the input sensing layer 40 may be located on the encapsulation layer 300. The optical functional layer 50 may be located on the input sensing layer 40. Because the second peripheral area RAP2 is a kind of non-display area, the black matrix 501 may be arranged in the second peripheral area RAP2, and the overcoat layer 503 may be located on the black matrix 501. The planarization organic layer 450 may be between the first insulating layer 401 and the second insulating layer 403 of the input sensing layer 40. A portion of the planarization organic layer 450 may overlap a portion of the organic encapsulation layer 320. The planarization organic layer 450 may planarize the second peripheral area RAP2 by overlapping the third groove 3G and/or the second partition wall PW2 that does not overlap the organic encapsulation layer 320.

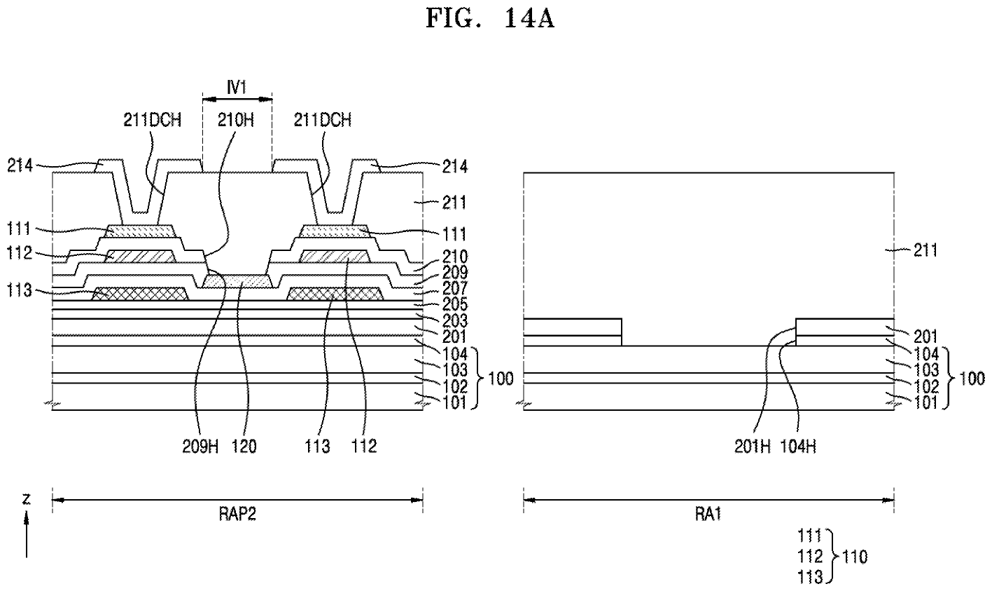

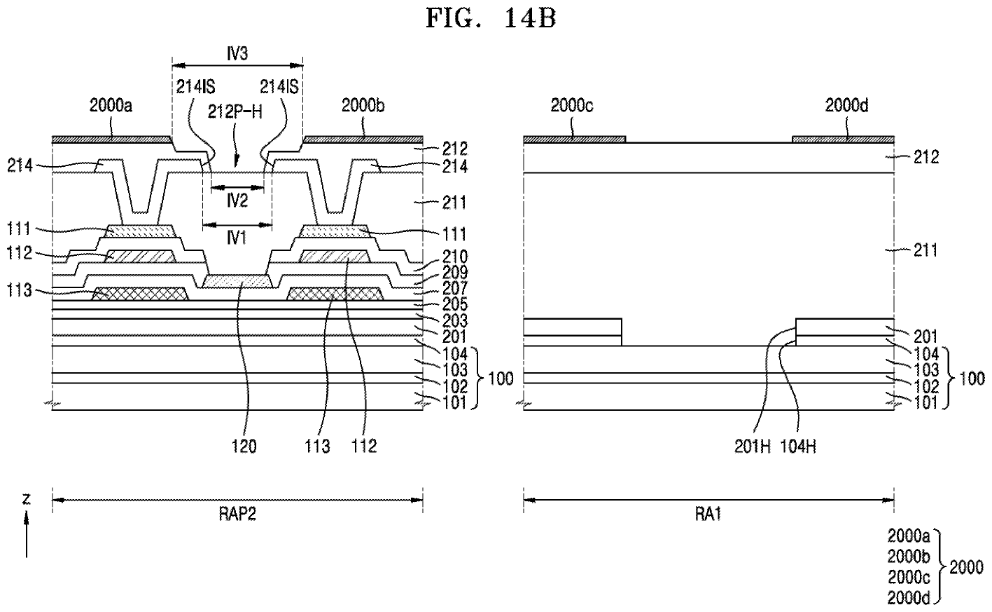

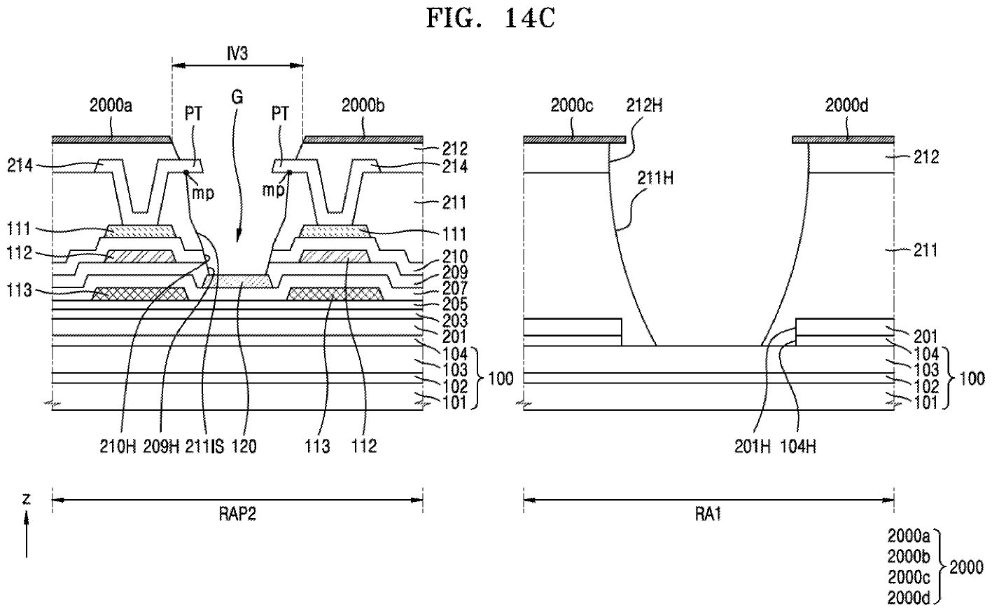

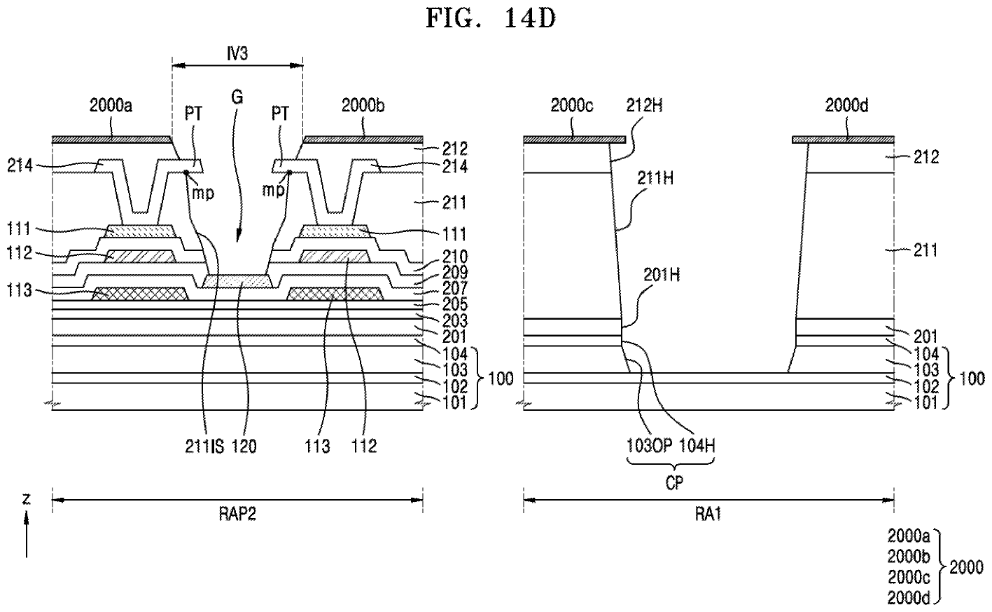

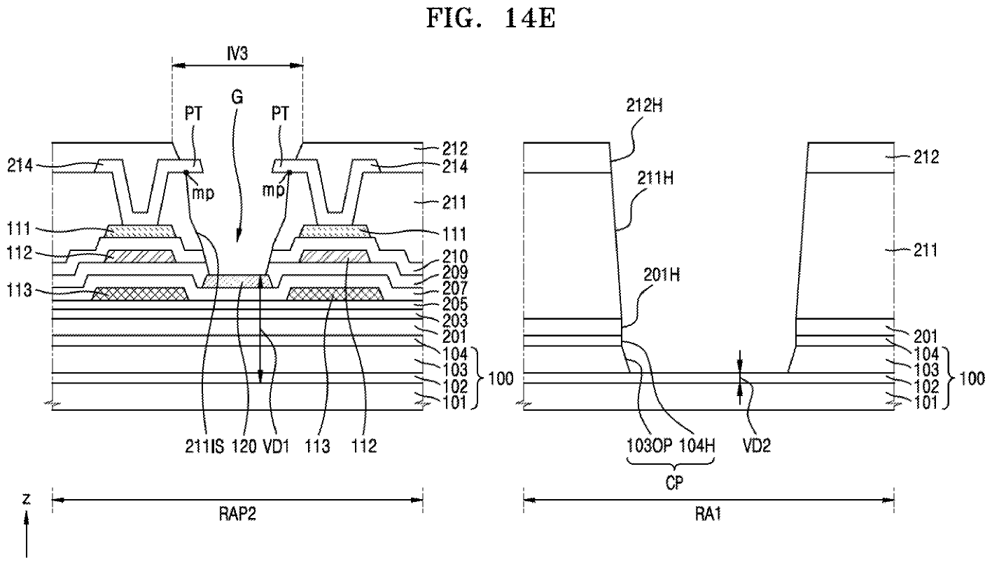

FIGS. 14A to 14E are cross-sectional views illustrating an operation of forming a concave portion and a groove of a display panel according to some embodiments. Each of FIGS. 14A to 14E illustrates the first area RA1 in which a concave portion is to be formed and the second peripheral area RAP2 in which a groove is to be formed, for convenience of description.

Referring to FIG. 14A, the substrate 100 is prepared. The substrate 100 may include the first base layer 101, the first barrier layer 102, the second base layer 103, and the second barrier layer 104. Insulating layers may be formed on the substrate 100.

Referring to the second peripheral area RAP2 of FIG. 14A, the buffer layer 201, the first gate insulating layer 203, the first interlayer insulating layer 205, the second interlayer insulating layer 207, the second gate insulating layer 209, the third interlayer insulating layer 210, and the first organic insulating layer 211 may be formed on the substrate 100. In the second peripheral area RAP2, the metal dummy stack 110 may be arranged on each of both sides of the lower layer 120 with the lower layer 120 therebetween. Each of the metal dummy stacks 110 may include a first metal layer 111, a second metal layer 112 below the first metal layer 111, and a third metal layer 113 below the second metal layer 112. The third metal layer 113 may be between the first interlayer insulating layer 205 and the second interlayer insulating layer 207, the second metal layer 112 may be between the second gate insulating layer 209 and the third interlayer insulating layer 210, and the first metal layer 111 may between the third interlayer insulating layer 210 and the first organic insulating layer 211.

The lower layer 120 may be formed on the second interlayer insulating layer 207. The lower layer 120 may be formed together with the third semiconductor layer A3 described above with reference to FIG. 7 in the same operation.

The second gate insulating layer 209 and the third interlayer insulating layer 210 are formed on the lower layer 120, and the second gate insulating layer 209 and the third interlayer insulating layer 210 may respectively include holes 209H and 210H, which overlap the lower layer 120. The upper surface of the lower layer 120 may be in contact with the first organic insulating layer 211 through the holes 209H and 210H of the second gate insulating layer 209 and the third interlayer insulating layer 210, respectively.

The metal pattern layer 214 may be formed on the first organic insulating layer 211. The metal pattern layer 214 may be formed by forming an entire metal material layer on the first organic insulating layer 211 and then patterning the metal material layer by using a mask, such as a photoresist. By patterning the metal material layer, the metal pattern layers 214, which are spaced apart from each other, may be formed on the first organic insulating layer 211.

Two adjacent metal pattern layers 214 may be respectively arranged on both sides of the lower layer 120 with the lower layer 120 therebetween. For example, two adjacent metal pattern layers 214 may be spaced apart from each other with a first separation area IV1 therebetween. The first separation area IV1 corresponds to a separation distance (e.g., a separation distance in a horizontal direction) between end portions of two metal pattern layers 214. A portion of the first organic insulating layer 211 (e.g., a portion overlapping the lower layer 120) may be exposed through the first separation area IV1.

Each metal pattern layer 214 may be in direct contact with the first metal layer 111 therebelow through a dummy contact hole 211DCH. Through the contact between the metal pattern layer 214 and the first metal layer 111, moisture that may travel through the first organic insulating layer 211 may be blocked.

Referring to the first area RA1 of FIG. 14A, the buffer layer 201 may be located on the substrate 100, and the buffer layer 201 may include a hole 201H. The second barrier layer 104, which is the uppermost layer of the substrate 100, may include a hole 104H.

The hole 104H of the second barrier layer 104 and the hole 201H of the buffer layer 201 may be formed together in an operation for forming a contact hole for electrical connection between the first semiconductor layer A1 (refer to FIG. 7) and an electrode or line and/or an operation for forming a contact hole for electrical connection between the third semiconductor layer A3 (refer to FIG. 7) and an electrode or line. The first organic insulating layer 211 may be located on the buffer layer 201.

Referring to FIG. 14B, the second organic insulating layer 212 is formed in the second peripheral area RAP2 and the first area RA1. The second organic insulating layer 212 may include a hole 212P-H overlapping the first separation area IV1. The width of the hole 212P-H of the second organic insulating layer 212, for example, the width of a second separation area IV2 between portions of the second organic insulating layer 212, the portions being spaced apart from each other with the hole 212P-H therebetween, may be less than the width of the first separation area IV1. Accordingly, a side surface 214IS of each of the metal pattern layers 214, which face each other, may be covered with the second organic insulating layer 212.

Thereafter, a mask 2000 is formed on the second organic insulating layer 212. The mask 2000 may be a hard mask including a non-photosensitive material, for example, a semiconductor material. For example, the mask 2000 may include IGZO.

The mask 2000 may include a first mask portion 2000a and a second mask portion 2000b, which are in the second peripheral area RAP2. The first mask portion 2000a and the second mask portion 2000b may respectively overlap the metal pattern layers 214, which are spaced apart from each other. The width of a third separation area IV3 between the first mask portion 2000a and the second mask portion 2000b may be greater than the width of the first separation area IV1.

The mask 2000 may include a third mask portion 2000c and a fourth mask portion 2000d, which are spaced apart from each other with the hole 201H of the buffer layer 201 and the hole 104H of the second barrier layer 104 therebetween, in the first area RA1. The third mask portion 2000c and the fourth mask portion 2000d may respectively overlap portions of the second barrier layer 104, the portions being spaced apart from each other with the hole 104H therebetween. A separation area between the third mask portion 2000c and the fourth mask portion 2000d may overlap the hole 104H of the second barrier layer 104 and the hole 201H of the buffer layer 201.

Referring to FIG. 14C, a portion of an organic insulating layer in each of the second peripheral area RAP2 and the first area RA1 may be removed by using the mask 2000 (a first removal operation). According to the first removal operation, the groove G having an undercut shape may be formed in the second peripheral area RAP2, and the hole 211H of the first organic insulating layer 211 and the hole 212H of the second organic insulating layer 212 may be formed in the first area RA1.

In the second peripheral area RAP2, the groove G may be formed while removing a portion of the first organic insulating layer 211 located below the third separation area IV3 between the first mask portion 2000a and the second mask portion 2000b. When a portion of the first organic insulating layer 211 is removed, a portion of the second organic insulating layer 212, the portion not overlapping each of the first mask portion 2000a and the second mask portion 2000b, may also be removed. The groove G formed while a portion of the first organic insulating layer 211 is removed may overlap the holes 209H and 210H of the second gate insulating layer 209 and the third interlayer insulating layer 210, respectively. Accordingly, an effect of increasing the depth of the groove G may be obtained.

As a portion of the first organic insulating layer 211 located below the metal pattern layer 214 is removed, a portion of the metal pattern layer 214 may further extend toward the center of the groove G by passing a point mp where an inner side surface 211IS of the first organic insulating layer 211 and a lower surface of the metal pattern layer 214 meet each other. The portion of the metal pattern layer 214, the portion further extending toward the center of the groove G by passing the point mp described above, corresponds to a tip PT.

In the first area RA1, while a portion of the first organic insulating layer 211 and a portion of the second organic insulating layer 212, which are located below the separation area between the third mask portion 2000c and the fourth mask portion 2000d, are removed, the hole 211H of the first organic insulating layer 211 and the hole 212H of the second organic insulating layer 212 may be formed.

Referring to FIG. 14D, a portion of the second base layer 103 below the second barrier layer 104 in the first area RA1 may be removed by using the mask 2000 (a second removal operation). A gas used in the second removal operation may also be injected into the second peripheral area RAP2. However, in the second peripheral area RAP2, because the lower layer 120 as an etch stopper exists, the depth of the groove G is not further increased, and an opening 1030P of the second base layer 103 may be included while a portion of the second base layer 103 in the first area RA1 is removed. FIG. 14D illustrates that the opening 1030P of the second base layer 103 has a shape of a hole penetrating through a bottom surface from an upper surface of the second base layer 103, but according to some embodiments, the opening 1030P of the second base layer 103 may be in a shape of a blind hole that is concave from the upper surface to the lower surface of the second base layer 103 and does not pass through the bottom surface of the second base layer 103.

The opening 1030P of the second base layer 103 and the hole 104H of the second barrier layer 104 may form the concave portion CP of the substrate 100.

Referring to FIG. 14E, the mask 2000 is removed. In the first removal operation and the second removal operation described above, the same etching material (e.g., a gas or the like) is provided to the first area RA1 and the second peripheral area RAP2, but the lower layer 120 is in the second peripheral area RAP2, and thus, the positions of the bottom surfaces of the groove G and the concave portion CP may be different from each other. For example, a first vertical distance VD1 from the upper surface of the first base layer 101 to the bottom surface of the groove G may be greater than a second vertical distance VD2 from the upper surface of the first base layer 101 to the bottom surface of the concave portion CP.

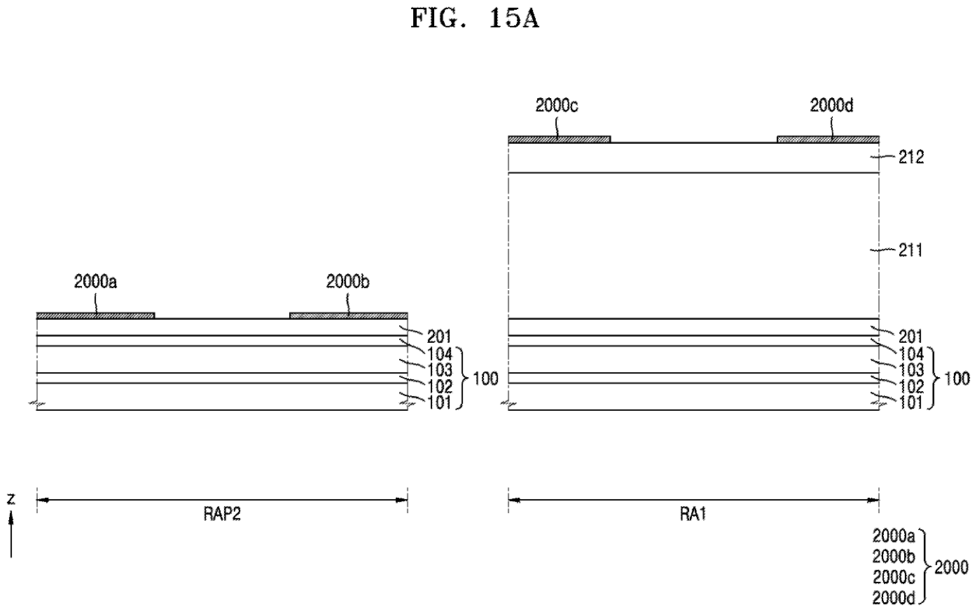

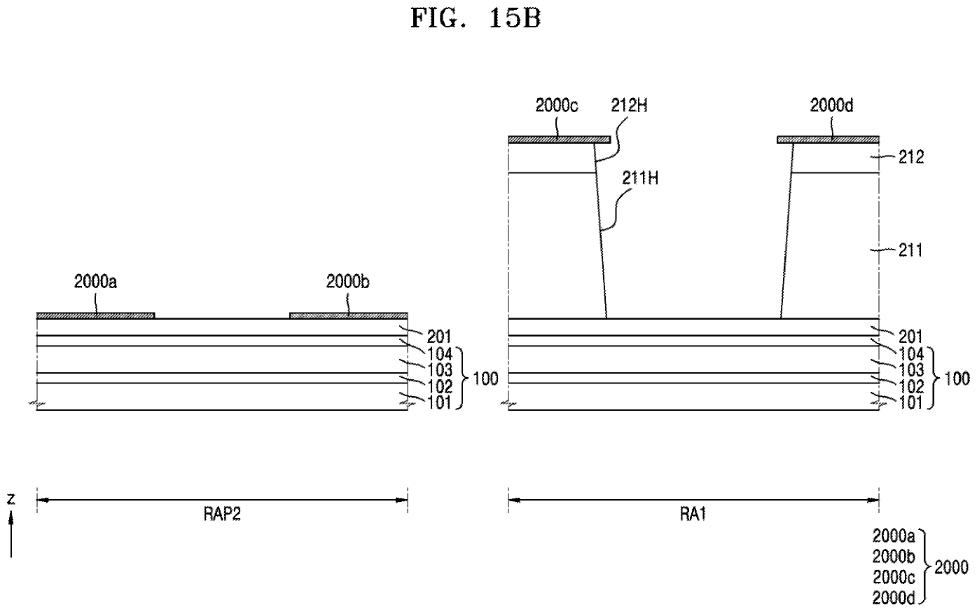

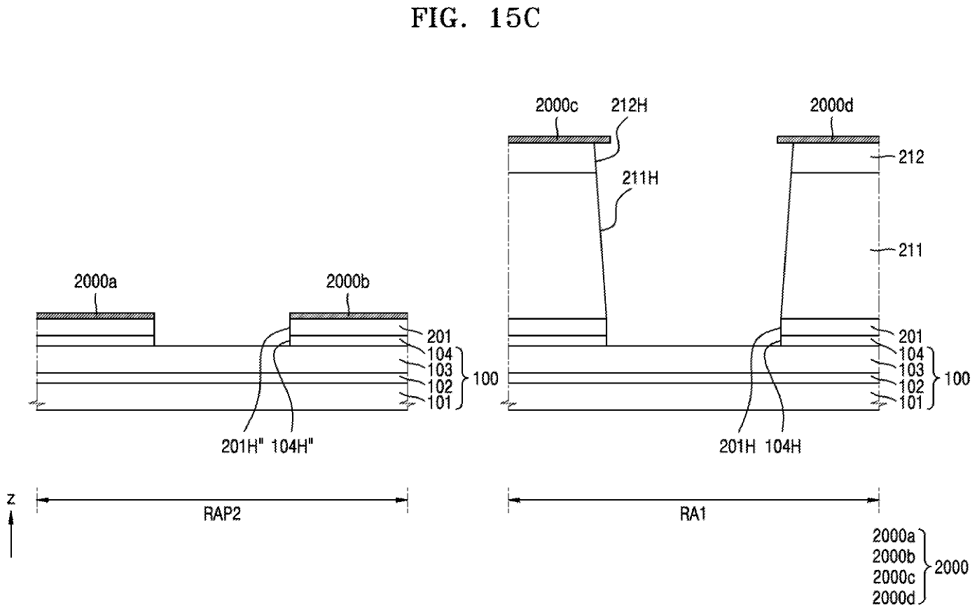

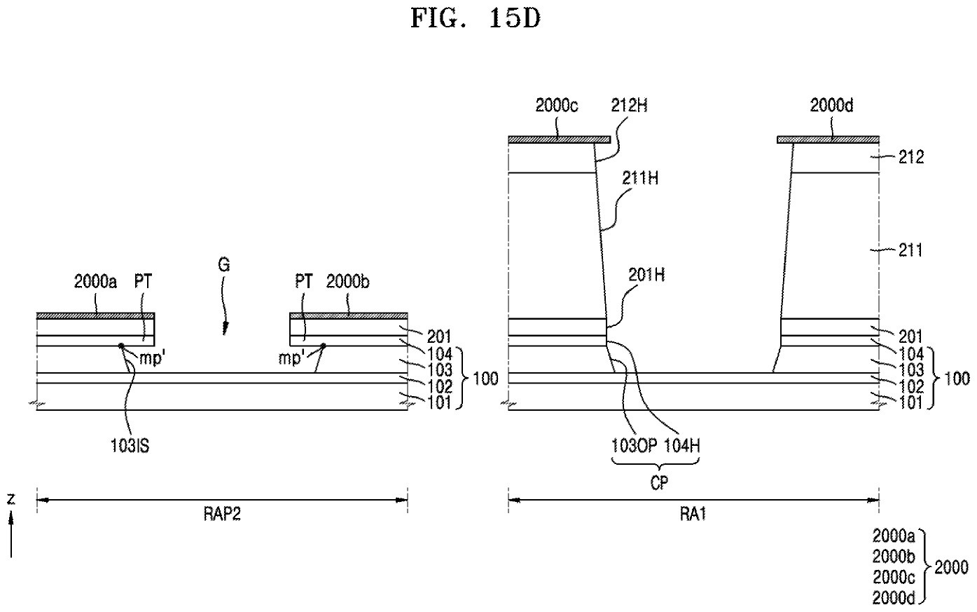

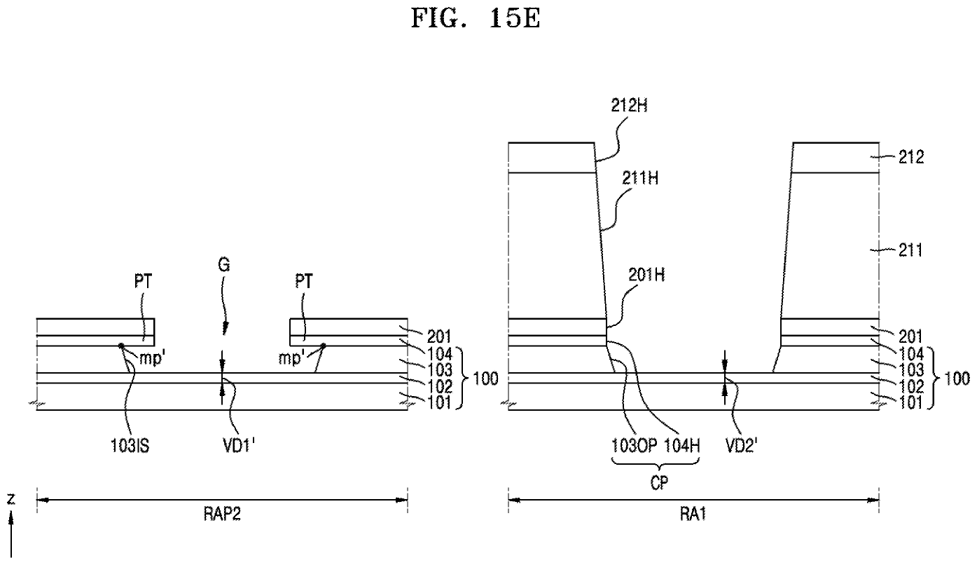

FIGS. 15A to 15E are cross-sectional views illustrating an operation of forming a concave portion and a groove of a display panel according to some embodiments.

Referring to FIG. 15A, the substrate 100 is prepared. The substrate 100 may include the first base layer 101, the first barrier layer 102, the second base layer 103, and the second barrier layer 104. Insulating layers may be formed on the substrate 100.

Referring to the second peripheral area RAP2 of FIG. 15A, the buffer layer 201 may be formed on the substrate 100. Referring to the first area RA1 of FIG. 15A, the buffer layer 201, the first organic insulating layer 211, and the second organic insulating layer 212 may be formed on the substrate 100. In other words, the first organic insulating layer 211 and the second organic insulating layer 212 may be formed in the first area RA1, but may not be formed in at least a portion of the second peripheral area RAP2 (e.g., an area in which a groove is to be formed).

Thereafter, the mask 2000 is formed. The mask 2000 may be a hard mask including a non-photosensitive material, for example, a semiconductor material. For example, the mask 2000 may include IGZO.

The mask 2000 may include the first mask portion 2000a and the second mask portion 2000b, which are spaced apart from each other, in the second peripheral area RAP2. The mask 2000 may include the third mask portion 2000c and the fourth mask portion 2000d, which are spaced apart from each other, in the first area RA1.

Referring to FIG. 15B, a portion of an organic insulating layer may be removed by using the mask 2000 (a first removal operation). A portion of the organic insulating layer, the portion being located below the mask 2000, may be removed by the first removal operation.

For example, according to the first removal operation, the hole 211H of the first organic insulating layer 211 and the hole 212H of the second organic insulating layer 212 may be formed in the first area RA1. On the contrary, in the second peripheral area RAP2, because no organic insulating layer is below the first mask portion 2000a and the second mask portion 2000b, there is no organic insulating layer to be removed.

Referring to FIG. 15C, a portion of an inorganic insulating layer(s) may be removed by using the mask 2000 (a second removal operation). In the second removal operation, a portion of the inorganic insulating layer(s) in each of the second peripheral area RAP2 and the first area RA1 may be removed.

Referring to the second peripheral area RAP2, the holes 210H″ and 104H″ of the buffer layer 201 and the second barrier layer 104 may be formed while a portion of each of the buffer layer 201 and the second barrier layer 104, which overlap the separation area between the first mask portion 2000a and the second mask portion 2000b, is removed.

Referring to the first area RA1, the holes 201H and 104H of the buffer layer 201 and the second barrier layer 104 may be formed while a portion of each of the buffer layer 201 and the second barrier layer 104, which are below the hole 211H of the first organic insulating layer 211 and the hole 212H of the second organic insulating layer 212, is removed.

Referring to FIG. 15D, a layer below the second barrier layer 104, for example, a portion of the second base layer 103, may be removed by using the mask 2000 (a third removal operation). Through the third removal operation, a groove G having an undercut shape may be formed in the second peripheral area RAP2, and the concave portion CP may be formed in the first area RA1.

Referring to the second peripheral area RAP2, the groove G is formed while a portion of the second base layer 103, the portion overlapping a separation area between the first mask portion 2000a and the second mask portion 2000b, is removed. While a portion of the second base layer 103 having a different etch

selectivity from that of the second barrier layer 104 is removed, a portion of the second barrier layer 104 may further extend toward the center of the groove G by passing by a point mp′ where an inner side surface 103IS of the second base layer 103 and the bottom surface of the second barrier layer 104 meet each other. The portion of the second barrier layer 104, the portion further extending toward the center of the groove G by passing the point mp′ described above, corresponds to a tip PT.

Referring to the first area RA1, the opening 1030P of the second base layer 103 may be formed while a portion of the second base layer 103, the portion being below the hole 211H of the first organic insulating layer 211, the hole 212H of the second organic insulating layer 212, the hole 201H of the buffer layer 201, and the hole 104H of the second barrier layer 104, is removed.

FIG. 15D illustrates that each of the groove G formed in the second base layer 103 in the second peripheral area RAP2 and the opening 1030P formed in the second base layer 103 in the first area RA1 penetrates through the bottom surface from the upper surface of the second base layer 103. According to some embodiments, the opening 1030P of the second base layer 103 may have a shape of a blind hole that is concave from the upper surface to the lower surface of the second base layer 103 and does not pass through the bottom surface of the second base layer 103. Similarly, the groove G may also not be formed to pass through the second base layer 103.

In other words, FIG. 15D illustrates that each of the bottom surface of the groove G and the bottom surface of the concave portion CP is substantially the same as the upper surface of the first barrier layer 102, but embodiments according to the present disclosure are not limited thereto. According to some embodiments, the bottom surface of the groove G and the bottom surface of the concave portion CP may each be arranged farther from the first base layer 101 than the upper surface of the first barrier layer 102.

Referring to FIG. 15E, the mask 2000 is removed. Because the groove G and the concave portion CP are together formed in the third removal operation described above, the bottom surfaces of the groove G and the concave portion CP may be substantially the same. For example, a first vertical distance VD1′ from the upper surface of the first base layer 101 to the bottom surface of the groove G may be substantially equal to a second vertical distance VD2′ from the upper surface of the first base layer 101 to the bottom surface of the concave portion CP.

According to some embodiments, a groove and a concave portion may be simultaneously or concurrently formed without adding a process using a mask, thereby reducing cost. According to some embodiments, a position where a component is arranged may be minimized to be recognized by a user, and the area of a transmission area through which a wave (e.g., light or sound) that travels to a component or occurs in a component may pass may be secured. However, these effects are merely illustrations, and the scope of embodiments according to the present disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display panel comprising:
a substrate comprising a first area, a second area spaced apart from the first area, and a first display area surrounding the first area and the second area;
a plurality of first sub-pixel circuits in the first display area;
a plurality of first light-emitting diodes in the first display area and respectively electrically connected to the plurality of first sub-pixel circuits;
a plurality of second light-emitting diodes in the first area;
a plurality of second sub-pixel circuits respectively electrically connected to the plurality of second light-emitting diodes; and
a groove surrounding the second area and having an undercut shape,
wherein the substrate comprises a first base layer, a first barrier layer on the first base layer, a second base layer on the first barrier layer, and a second barrier layer on the second base layer,
wherein the substrate further comprises:
a first concave portion corresponding to a region between two adjacent second light-emitting diodes in the first area and having a shape recessed into the second barrier layer and the second base layer; and
a hole corresponding to the second area and penetrating through the second barrier layer, the second base layer, the first barrier layer, and the first base layer.

2. The display panel of claim 1, wherein a first vertical distance from an upper surface of the first base layer to a bottom surface of the groove is equal to or greater than a second vertical distance from the upper surface of the first base layer to a bottom surface of the first concave portion.

3. The display panel of claim 1, wherein the first area comprises a transmission area corresponding to the first concave portion of the substrate.

4. The display panel of claim 1, wherein one of two second sub-pixel circuits selected from among the plurality of second sub-pixel circuits is in a first peripheral area on a first side of the first area, and another one of the two second sub-pixel circuits is in a second peripheral area on a second side of the first area, the second side being opposite to the first side.

5. The display panel of claim 4, wherein the one of the two second sub-pixel circuits is on a side opposite to the second area with the first area therebetween, and
the other one of the two second sub-pixel circuits is between the first area and the second area.

6. The display panel of claim 4, further comprising:
a first conductive bus line electrically connecting the one of the two second sub-pixel circuits and a corresponding second light-emitting diode from among the plurality of second light-emitting diodes to each other and extending in a first direction; and
a second conductive bus line electrically connecting the other one of the two second sub-pixel circuits and a corresponding second light-emitting diode from among the plurality of second light-emitting diodes to each other and extending in the first direction.

7. The display panel of claim 6, wherein each of the first conductive bus line and the second conductive bus line comprises a transmissive conductive material.

8. The display panel of claim 7, wherein a portion of any one of the first conductive bus line and the second conductive bus line overlaps the first concave portion.

9. The display panel of claim 1, wherein a first height from the substrate to a first electrode of any one of the plurality of second light-emitting diodes in the first area is less than a second height from the substrate to a first electrode of any one of the plurality of first light-emitting diodes in the first display area.

10. The display panel of claim 1, further comprising an organic insulating layer between the substrate and a first electrode of any one of the plurality of second light-emitting diodes in the first area,
wherein the organic insulating layer overlaps the first concave portion of the substrate.

11. The display panel of claim 1, wherein the substrate further comprises a second concave portion in the first area and spaced apart from the first concave portion.

12. A method of manufacturing a display panel, the display panel comprising:
a first display area in which a plurality of first light-emitting diodes is arranged;
a first area in which a plurality of second light-emitting diodes is arranged; and
a second area spaced apart from the first area, the method comprising:
preparing a substrate comprising a first base layer, a first barrier layer on the first base layer, a second base layer on the first barrier layer, and a second barrier layer on the second base layer, wherein the plurality of first light-emitting diodes and the plurality of second light-emitting diodes are on the substrate;
forming a groove corresponding to a peripheral area of the second area, surrounding the second area, and having an undercut shape; and
forming a concave portion corresponding to a region between two adjacent second light-emitting diodes in the first area and having a shape recessed into the second barrier layer and the second base layer,
wherein, in the forming of the groove and the forming of the concave portion, a mask made of a same material is used.

13. The method of claim 12, wherein the mask comprises indium gallium zinc oxide (IGZO).

14. The method of claim 12, wherein a first vertical distance from an upper surface of the first base layer to a bottom surface of the groove is equal to or greater than a second vertical distance from the upper surface of the first base layer to a bottom surface of the concave portion.

15. The method of claim 12, wherein the forming of the concave portion comprises:
forming a hole penetrating through the second barrier layer; and
forming an opening overlapping the hole of the second barrier layer in the second base layer.

16. The method of claim 15, further comprising:
forming an organic insulating layer between the substrate and the mask; and
forming a metal pattern layer on the organic insulating layer,
wherein the forming of the groove comprises removing a portion of the organic insulating layer by using the mask, and
the metal pattern layer comprises a tip protruding toward the groove from a point where an inner side surface of the organic insulating layer, from which a portion thereof is removed, and a bottom surface of the metal pattern layer meet each other.

17. The method of claim 16, further comprising forming a lower layer below the organic insulating layer.

18. The method of claim 15, wherein the forming of the groove comprises:
forming a hole penetrating through the second barrier layer below the mask; and
forming an opening overlapping the hole of the second barrier layer in the second base layer.

19. An electronic apparatus comprising:
a display panel comprising a first area, a second area spaced apart from the first area, and a first display area surrounding the first area and the second area;
a first component corresponding to the first area of the display panel and on a rear surface of the display panel; and
a second component corresponding to the second area of the display panel and on the rear surface of the display panel,
wherein the display panel comprises:
a substrate;
a plurality of first sub-pixel circuits on the substrate and in the first display area;
a plurality of first light-emitting diodes in the first display area and respectively electrically connected to the plurality of first sub-pixel circuits;
a plurality of second light-emitting diodes in the first area;
a plurality of second sub-pixel circuits respectively electrically connected to the plurality of second light-emitting diodes; and
a groove surrounding the second area and having an undercut shape,
wherein the substrate comprises a first base layer, a first barrier layer on the first base layer, a second base layer on the first barrier layer, and a second barrier layer on the second base layer,
wherein the substrate further comprises:
a first concave portion corresponding to a region between two adjacent second light-emitting diodes in the first area and having a shape recessed into the second barrier layer and the second base layer; and
a hole corresponding to the second area and penetrating through the second barrier layer, the second base layer, the first barrier layer, and the first base layer.

20. The electronic apparatus of claim 19, wherein a first vertical distance from an upper surface of the first base layer to a bottom surface of the groove is equal to or greater than a second vertical distance from the upper surface of the first base layer to a bottom surface of the first concave portion.

21. The electronic apparatus of claim 19, wherein the first area comprises a transmission area corresponding to the first concave portion of the substrate.

22. The electronic apparatus of claim 19, wherein one of two second sub-pixel circuits selected from among the plurality of second sub-pixel circuits is in a first peripheral area on a first side of the first area, and another one of the two second sub-pixel is in a second peripheral area on a second side of the first area, the second side being opposite to the first side.

23. The electronic apparatus of claim 22, wherein the display panel further comprises:
a first conductive bus line electrically connecting the one of the two second sub-pixel circuits and a corresponding second light-emitting diode from among the plurality of second light-emitting diodes to each other and extending in a first direction; and
a second conductive bus line electrically connecting the other one of the two second sub-pixel circuits and a corresponding second light-emitting diode from among the plurality of second light-emitting diodes to each other and extending in the first direction.

24. The electronic apparatus of claim 23, wherein each of the first conductive bus line and the second conductive bus line comprises a transmissive conductive material.

25. The electronic apparatus of claim 24, wherein a portion of any one of the first conductive bus line and the second conductive bus line overlaps the first concave portion.

26. The electronic apparatus of claim 19, wherein a first height from the substrate to a first electrode of any one of the plurality of second light-emitting diodes in the first area is less than a second height from the substrate to a first electrode of any one of the plurality of first light-emitting diodes in the first display area.

27. The electronic apparatus of claim 19, wherein the display panel further comprises an organic insulating layer between the substrate and a first electrode of any one of the plurality of second light-emitting diodes in the first area, and
the organic insulating layer overlaps the first concave portion of the substrate.

28. The electronic apparatus of claim 19, wherein the substrate further comprises a second concave portion in the first area and spaced apart from the first concave portion.

29. The electronic apparatus of claim 19, wherein each of the first component and the second component comprises an electronic element using light, and the electronic element of the first component is different from the electronic element of the second component.

30. The electronic apparatus of claim 29, wherein the electronic element of each of the first component and the second component comprises a sensor or a camera.
